(19) United States
(12) Patent Application Publication
(10) Pub. No.: US 2025/0149297 A1
(43) Pub. Date: May 8, 2025

(54) PLASMA PROCESSING APPARATUS AND METHOD FOR CONTROLLING POWER STORAGE AMOUNT

(71) Applicant: Tokyo Electron Limited, Tokyo (JP)

(72) Inventors: Nozomu NAGASHIMA, Miyagi (JP); Daisuke YOSHIKOSHI, Miyagi (JP); Kunihiko YAMAGATA, Miyagi (JP)

(73) Assignee: Tokyo Electron Limited, Tokyo (JP)

(21) Appl. No.: 19/003,142

(22) Filed: Dec. 27, 2024

Related U.S. Application Data
(63) Continuation of application No. PCT/JP2023/019150, filed on May 23, 2023.
(60) Provisional application No. 63/356,713, filed on Jun. 29, 2022.

(51) Int. Cl. H01J 37/32

(52) U.S. Cl. CPC H01J 37/32174

(57) ABSTRACT

A plasma processing apparatus comprises a plasma processing chamber, a substrate support, a high frequency power supply, an electrode or an antenna, a power consuming member, a ground frame, an electricity storage unit, a rectifying and smoothing unit, a power feeding output connector, and a power receiving coil. The rectifying and smoothing unit includes a power feeding input connector comprising a first power feeding input terminal and a second power feeding input terminal, and a rectifying circuit comprising a diode bridge. The power feeding output connector comprises a first feeding output terminal and a second power feeding output terminal which are electrically connectable to the first power feeding input terminal and the second power feeding input terminal. The power receiving coil is electrically connected to the power feeding output connector, and capable of receiving power from a power transmitting coil by electromagnetic induction coupling.

### CROSS-REFERENCE TO RELATED APPLICATIONS

This application is a bypass continuation application of International Application No. PCT/JP2023/019150 having an international filing date of May 23, 2023 and designating the United States, the International Application being based upon and claiming the benefit of priority from the U.S. Provisional Patent Application No. 63/356,713 filed on Jun. 29, 2022, the entire contents of each are incorporated herein by reference.

### TECHNICAL FIELD

An exemplary embodiment of the present disclosure relates to a plasma processing apparatus and a method for controlling a power storage amount.

### BACKGROUND

The plasma processing apparatus is used in the plasma processing. The plasma processing apparatus includes a chamber and a substrate support (mounting table) disposed within the chamber. The substrate support has a base (lower electrode) and an electrostatic chuck that holds a substrate. A temperature adjustment element (for example, a heater) for adjusting the temperature of the substrate is provided inside the electrostatic chuck. In addition, a filter is provided between the temperature adjustment element and a power supply for the temperature adjustment element to attenuate or block high frequency noise entering lines such as power-feeding lines and/or signal wires from high frequency electrodes and/or other electrical members within the chamber. One type of such plasma processing apparatus is disclosed in Japanese Laid-open Patent Publication No. 2015-173027.

### SUMMARY

An exemplary embodiment of the present disclosure provides a technology for controlling a power storage amount of an electricity storage unit of a plasma processing apparatus.

According to an exemplary embodiment, a plasma processing apparatus is provided. The plasma processing apparatus comprises a plasma processing chamber, a substrate support, a high frequency power supply, an electrode or an antenna, a power consuming member, a ground frame, an electricity storage unit, a rectifying and smoothing unit, a power feeding output connector, and a power receiving coil. The substrate support is disposed within the plasma processing chamber. The high frequency power supply is configured to generate high frequency power. The electrode or the antenna is electrically connected to the high frequency power supply to receive the high frequency power for generating a plasma from a gas within the plasma processing chamber. The power consuming member is disposed within the plasma processing chamber or the substrate support. The ground frame, that is grounded, surrounds the substrate support together with the plasma processing chamber. The electricity storage unit is disposed within a space surrounded by the ground frame and is electrically connected to the power consuming member. The rectifying and smoothing unit, disposed within the space surrounded by the ground frame, includes: a power feeding input connector comprising a first power feeding input terminal and a second power feeding input terminal and provided so as to be accessible from an outside of the ground frame, and a rectifying circuit comprising a diode bridge and connected between the power feeding input connector and the electricity storage unit. The power feeding output connector comprises a first feeding output terminal and a second power feeding output terminal which are electrically connectable to the first power feeding input terminal and the second power feeding input terminal, the power feeding output connector being detachable from the power feeding input connector. The power receiving coil, disposed outside the ground frame, is electrically connected to the power feeding output connector, and capable of receiving power from a power transmitting coil by electromagnetic induction coupling.

### BRIEF DESCRIPTION OF THE DRAWINGS

FIG. 1 is a diagram illustrating an example of a configuration of a plasma processing system.

FIG. 2 is a diagram illustrating an example of a configuration of a capacitively coupled plasma processing apparatus.

FIG. 3 is a diagram schematically illustrating a plasma processing apparatus according to one exemplary embodiment.

FIG. 4 is a diagram schematically illustrating a plasma processing apparatus according to another exemplary embodiment.

FIG. 5 is a diagram schematically illustrating a plasma processing apparatus according to yet another exemplary embodiment.

FIG. 6 is a diagram schematically illustrating a plasma processing apparatus according to yet another exemplary embodiment.

FIG. 7 is a diagram schematically illustrating a plasma processing apparatus according to yet another exemplary embodiment.

FIG. 8 is a diagram illustrating a power transmission unit according to one exemplary embodiment.

FIG. 9 is a diagram illustrating a power transmitting coil unit and a power receiving coil unit according to one exemplary embodiment.

FIG. 10 is a diagram illustrating a power transmitting coil unit and a power receiving coil unit according to one exemplary embodiment.

FIG. 11 is a diagram illustrating a power transmitting coil unit and a power receiving coil unit according to one exemplary embodiment.

FIG. 12 is a graph showing the impedance characteristics of a power receiving coil unit according to one exemplary embodiment.

FIG. 13 is a diagram illustrating an RF filter according to one exemplary embodiment.

FIG. 14 is a diagram illustrating a rectifying and smoothing unit according to one exemplary embodiment.

FIG. 15 is a diagram illustrating an RF filter according to one exemplary embodiment.

FIG. 16 is a diagram illustrating a communication unit of a power transmission unit and a communication unit of a rectifying and smoothing unit according to one exemplary embodiment.

FIG. 17 is a diagram schematically illustrating a plasma processing apparatus according to yet another exemplary embodiment.

FIG. 18 is a diagram schematically illustrating a plasma processing apparatus according to yet another exemplary embodiment.

FIG. 19 is a diagram illustrating a communication unit of a power transmission unit and a communication unit of a rectifying and smoothing unit according to another exemplary embodiment.

FIG. 20 is a diagram schematically illustrating a plasma processing apparatus according to yet another exemplary embodiment.

FIG. 21 is a diagram schematically illustrating a plasma processing apparatus according to yet another exemplary embodiment.

FIG. 22 is a diagram schematically illustrating a plasma processing apparatus according to yet another exemplary embodiment.

Each of FIGS. 23A and 23B is a diagram illustrating an electricity storage unit according to one exemplary embodiment.

FIG. 24 is a diagram illustrating a voltage control converter according to one exemplary embodiment.

FIG. 25 is a diagram illustrating a constant voltage controller according to one exemplary embodiment.

FIG. 26 is a diagram illustrating a constant voltage controller according to another exemplary embodiment.

FIG. 27 is a diagram schematically illustrating a plasma processing apparatus according to yet another exemplary embodiment.

FIG. 28 is a diagram illustrating charging of an electricity storage unit of a plasma processing apparatus according to yet another exemplary embodiment.

FIG. 29 is a diagram schematically illustrating of a plasma processing apparatus according to yet another exemplary embodiment.

FIG. 30 is a diagram illustrating a state in which a power receiving coil unit is connected to a rectifying and smoothing unit of the plasma processing apparatus shown in FIG. 29.

FIG. 31 is a diagram illustrating a state in which a DC stabilized power supply is connected to the rectifying and smoothing unit of the plasma processing apparatus shown in FIG. 29.

FIG. 32A is a timing chart showing an example of a voltage of the electricity storage unit, and FIG. 32B is a timing chart showing an example of a current supplied to the electricity storage unit.

FIG. 33 is a diagram schematically illustrating a plasma processing apparatus according to yet another exemplary embodiment.

FIG. 34 is a diagram illustrating a state in which a power receiving coil unit is connected to a rectifying and smoothing unit of a plasma processing apparatus according to yet another exemplary embodiment.

FIG. 35 is a diagram illustrating a state in which a DC stabilized power supply is connected to a rectifying and smoothing unit of a plasma processing apparatus according to yet another exemplary embodiment.

FIG. 36 is a diagram illustrating a state in which a discharge unit is connected to a rectifying and smoothing unit of a plasma processing apparatus according to yet another exemplary embodiment.

FIG. 37 is a timing chart of an example of the voltage of the electricity storage unit.

FIG. 38 is diagram schematically illustrating a plasma processing apparatus according to yet another exemplary embodiment.

FIG. 39 is a diagram illustrating a configuration related to the discharge of the electricity storage unit in a plasma processing apparatus according to yet another exemplary embodiment.

FIG. 40 is a diagram illustrating a configuration related to the discharge of the electricity storage unit in a plasma processing apparatus according to yet another exemplary embodiment.

FIG. 41 is a timing chart of an example of the voltage of the electricity storage unit.

### DETAILED DESCRIPTION

Hereinafter, various exemplary embodiments will be described in detail with reference to the drawings, in which the same or corresponding portions are designated by the same reference numerals.

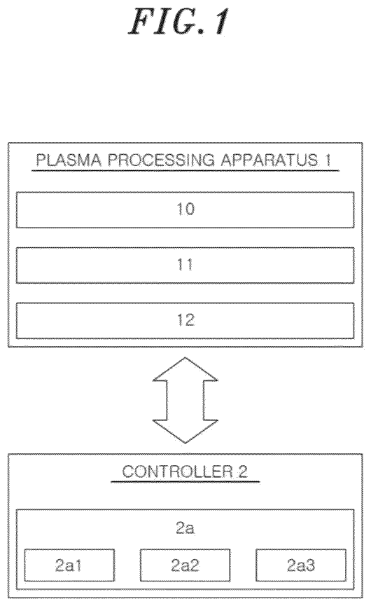

FIG. 1 is a diagram illustrating an example of a configuration of a plasma processing system. In an embodiment, the plasma processing system includes a plasma processing apparatus 1 and a controller (control circuitry, processing circuitry) 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas inlet for supplying at least one processing gas to the plasma processing space and at least one gas outlet for discharging the gas from the plasma processing space. The gas inlet is connected to a gas supply portion 20 to be described later, and the gas outlet is connected to an exhaust system 40 to be described later. The substrate support 11 is disposed within the plasma processing space and has a substrate support surface for supporting a substrate.

The plasma generator 12 is configured to generate a plasma from at least one processing gas supplied into the plasma processing space. The plasma formed in the plasma processing space may be a capacitively coupled plasma (CCP), an inductively coupled plasma (ICP), an electron-cyclotron-resonance (ECR) plasma, a helicon wave excited plasma (HWP), or a surface wave plasma (SWP). Further, various types of plasma generators including an alternating current (AC) plasma generator and a direct current (DC) plasma generator may be used. In an embodiment, an AC signal (AC power) used in the AC plasma generator has a frequency in a range of 100 kHz to 10 GHz. Thus, the AC signal includes a radio frequency (RF) signal and a microwave signal. In an embodiment, the RF signal has a frequency in a range of 100 kHz to 150 MHz.

The controller 2 processes a computer executable instruction that causes the plasma processing apparatus 1 to execute various processes described in an embodiment of the present disclosure. The controller 2 may be configured to control each element of the plasma processing apparatus 1 so as to execute various processes described herein. In an embodiment, a part or all of the controller 2 may be included in the plasma processing apparatus 1. The controller 2 may include a processor 2a1, a memory unit 2a2, and a communication interface 2a3. The controller 2 is realized by, for example, a computer 2a. The processor 2a1 may be configured to perform various control operations by reading out a program from the memory unit 2a2 and executing the read out program. This program may be stored in advance in the memory unit 2a2, or may be acquired via a medium when necessary. The acquired program is stored in the memory unit 2a2, and is read out from the memory unit 2a2 and executed by the processor 2a1. The medium may be any of various memory media readable by the computer 2a, or may be a communication line connected to the communication interface 2a3.

The processor 2a1 may be a central processing unit (CPU). The memory unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

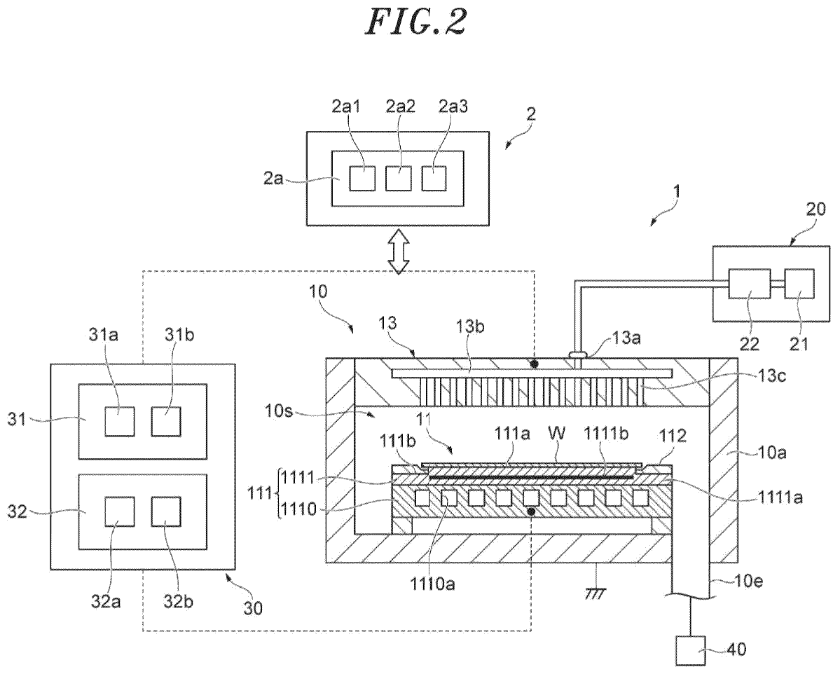

Hereinafter, the configuration example of a capacitively coupled plasma processing apparatus as an example of the plasma processing apparatus 1 will be described. FIG. 2 is a diagram illustrating an example of a configuration of a capacitively coupled plasma processing apparatus.

The capacitively coupled plasma processing apparatus 1 includes the plasma processing chamber 10, a gas supply portion 20, a power supply 30, and an exhaust system 40. Further, the plasma processing apparatus 1 includes the substrate support 11 and a gas introduction portion. The gas introduction portion is configured to introduce at least one processing gas into the plasma processing chamber 10. The gas introduction portion includes a shower head 13. The substrate support 11 is disposed within the plasma processing chamber 10. The shower head 13 is disposed above the substrate support 11. In an embodiment, the shower head 13 forms at least portion of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central area 111a for supporting a substrate W, and an annular area 111b for supporting the ring assembly 112. The wafer is an example of the substrate W. The annular area 111 b of the main body 111 surrounds the central area 111a of the main body 111 in a plan view. The substrate W is disposed on the central area 111a of the main body 111, and the ring assembly 112 is disposed on the annular area 111b of the main body 111 to surround the substrate W on the central area 111a of the main body 111. Accordingly, the central area 111a is also called a substrate support surface for supporting the substrate W, and the annular area 111 b is also called a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode (also called an adsorption electrode, a chuck electrode, or a clamp electrode) 1111b disposed within the ceramic member 1111a. The ceramic member 1111a has the central area 111a. In an embodiment, the ceramic member 1111a also has the annular area 111b. Further, other members surrounding the electrostatic chuck 1111, such as an annular electrostatic chuck or an annular insulating member, may be provided in the annular area 111b. In this connection, the ring assembly 112 may be disposed on the annular electrostatic chuck or the annular insulating member, and may be disposed on both the electrostatic chuck 1111 and the annular insulating member. Further, at least one RF/DC electrode coupled to an RF power supply 31 and/or a DC power supply 32, which will be described later, may be disposed within the ceramic member 1111a. In this connection, at least one RF/DC electrode functions as a lower electrode. When a bias RF signal and/or a DC signal, which will be described later, is supplied to at least one RF/DC electrode, the RF/DC electrode is also referred to as a bias electrode. Further, the conductive member of the base 1110 and at least one RF/DC electrode may function as a plurality of lower electrodes. Further, the electrostatic electrode 1111b may function as a lower electrode. Accordingly, the substrate support 11 includes at least one lower electrode.

The ring assembly 112 includes one or more annular members. In an embodiment, the one or more annular members include one or more edge rings and at least one cover ring. The edge ring is formed of a conductive or insulating material, and the cover ring is formed of an insulating material.

Further, the substrate support 11 may include a temperature control module configured to adjust at least one of the electrostatic chuck 1111, the ring assembly 112, and the substrate W to a target temperature. The temperature control module may include a heater, a heat transfer medium, a flow path 1110a, or a combination thereof. A heat transfer fluid such as brine or gas flows through the flow path 1110a. In an embodiment, the flow path 1110a is formed in the base 1110, and one or more heaters are disposed within the ceramic member 1111a of the electrostatic chuck 1111. Further, the substrate support 11 may include a heat transfer gas supply portion configured to supply heat transfer gas to a gap between the back surface of the substrate W and the central area 111a.

The shower head 13 is configured to introduce at least one processing gas from the gas supply portion 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and then is introduced from the plurality of gas introduction ports 13c into the plasma processing space 10s. Further, the shower head 13 includes at least one upper electrode. In addition to the shower head 13, the gas introduction portion may include one or more side gas injectors (SGI) installed in one or more openings formed in the side wall 10a.

The gas supply portion 20 may include at least one gas source 21 and at least one flow controller 22. In an embodiment, the gas supply portion 20 is configured to supply at least one processing gas from a corresponding gas source 21 through a corresponding flow controller 22 to the shower head 13. The flow controller 22 may include, for example, a mass flow controller or a pressure-controlled flow controller. Further, the gas supply portion 20 may include at least one flow modulation device that modulates or pulses the flow rate of at least one processing gas.

The power supply 30 includes an RF power supply 31 coupled to the plasma processing chamber 10 via at least one impedance matching circuit. The RF power supply 31 is configured to supply at least one RF signal (RF power) to at least one lower electrode and/or at least one upper electrode. Thereby, plasma is formed from at least one processing gas supplied to the plasma processing space 10s. Accordingly, the RF power supply 31 may function as at least a portion of the plasma generator 12. Further, by supplying a bias RF signal to at least one lower electrode, a bias potential may be generated on the substrate W, and ion components in the formed plasma may be attracted into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In an embodiment, the source RF signal has a frequency within the range of 10 MHz to 150 MHZ. In an embodiment, the first RF generator 31a may be configured to generate a plurality of source RF signals having different frequencies. One or more generated source RF signals are supplied to at least one lower electrode and/or at least one upper electrode.

The second RF generator 31b is coupled to at least one lower electrode via at least one impedance matching circuit, and is configured to generate a bias RF signal (bias RF power). The frequency of the bias RF signal may be equal to or different from the frequency of the source RF signal. In an embodiment, the bias RF signal has a frequency that is lower than the frequency of the source RF signal. In an embodiment, the bias RF signal has a frequency within the range of 100 KHz to 60 MHZ. In an embodiment, the second RF generator 31b may be configured to generate a plurality of bias RF signals having different frequencies. One or more generated bias RF signals are supplied to at least one lower electrode. Further, in various embodiments, at least one of the source RF signal and the bias RF signal may be pulsed.

The power supply 30 may also include the DC power supply 32 coupled to the plasma processing chamber 10. The DC power supply 32 includes a first DC generator 32a and a second DC generator 32b. In one embodiment, the first DC generator 32a is connected to at least one lower electrode and generates a first DC signal. The generated first DC signal is applied to at least one lower electrode. In one embodiment, the second DC generator 32b is connected to at least one upper electrode and generates a second DC signal. The generated second DC signal is applied to at least one upper electrode.

In various embodiments, the first DC signal or the second DC signal may be pulsed. In this connection, a sequence of voltage pulses is applied to at least one lower electrode and/or to at least one upper electrode. The voltage pulse may have a rectangular, trapezoidal, or triangular pulse waveform, or a combination of these pulse waveforms. In one embodiment, a waveform generator for generating a sequence of voltage pulses based on DC signals is connected between the first DC generator 32a and at least one lower electrode. Thus, the first DC generator 32a and the waveform generator are included in a voltage pulse generator. When the second DC generator 32b and the waveform generator are included in the voltage generator, the voltage pulse generator is connected to at least one upper electrode. The voltage pulses may have positive or negative polarity. The sequence of voltage pulses may also include one or more positive voltage pulses and one or more negative voltage pulses within one cycle. Further, the first DC generator 32a and the second DC generator 32b may be provided in addition to the RF power supply 31, or the first DC generator 32 a may replace the second RF generator 31b.

The exhaust system 40 may be, for example, connected to a gas outlet 10e in the bottom of the plasma processing chamber 10. The exhaust system 40 may include a pressure control valve and a vacuum pump. The pressure control valve regulates the pressure in the plasma processing space 10s. The vacuum pump may include a turbomolecular pump, a dry pump, or a combination of these.

Further, in the capacitively coupled plasma processing apparatus 1, the upper electrode is disposed so that the plasma processing space is located between the upper electrode and the substrate support 11. A high frequency power supply, such as the first RF generator 31a, is electrically connected to the upper electrode or the lower electrode within the substrate support 11. When the plasma processing apparatus 1 is an inductively coupled plasma processing apparatus, the antenna is disposed so that the plasma processing space is located between the antenna and the substrate support 11. The high frequency power supply, such as the first RF generator 31a, is electrically connected to the antenna. When the plasma processing apparatus 1 is a plasma processing apparatus that generates plasma by surface waves such as microwaves, the antenna is disposed so that the plasma processing space is located between the antenna and the substrate support 11. A high frequency power supply, such as the first RF generator 31a, is electrically connected to the antenna via a waveguide.

Hereinafter, plasma processing apparatuses according to various exemplary embodiments will be described. Each of the plasma processing apparatuses described below is configured to supply power to at least one power consuming member in the chamber 10 by wireless power feeding (electromagnetic inductive coupling) and may have the same configuration as the plasma processing apparatus 1.

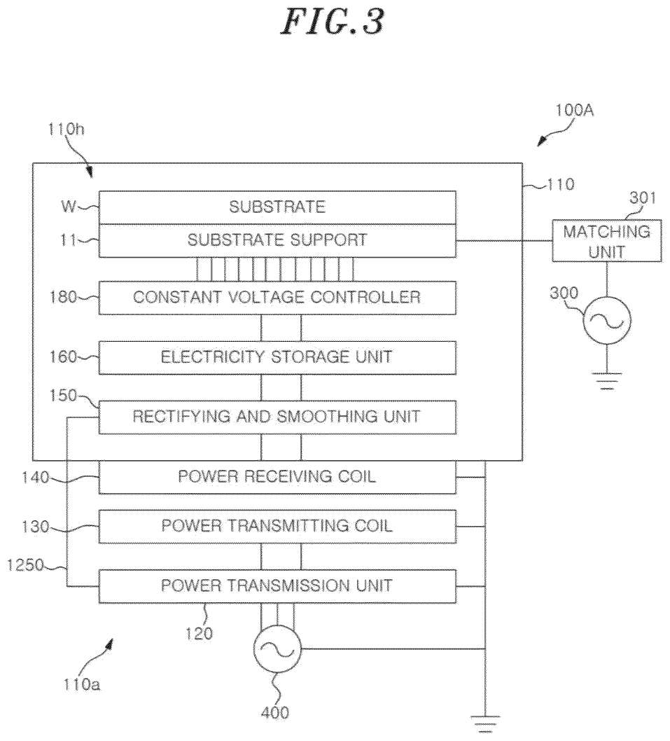

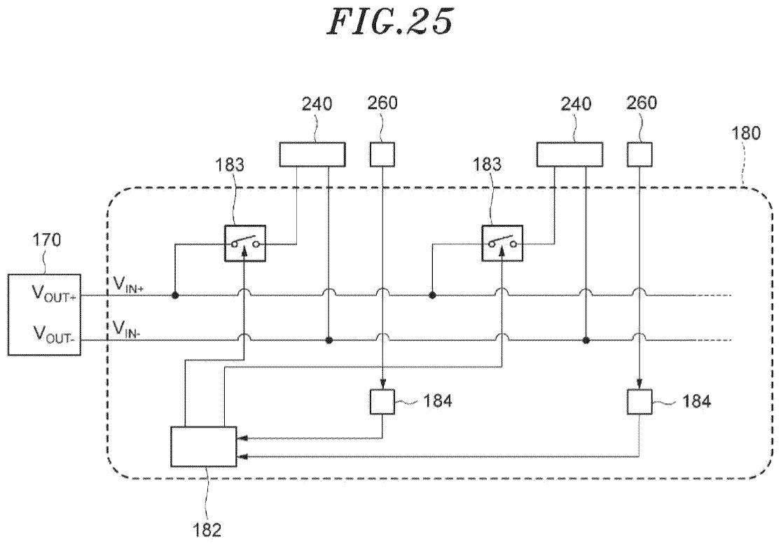

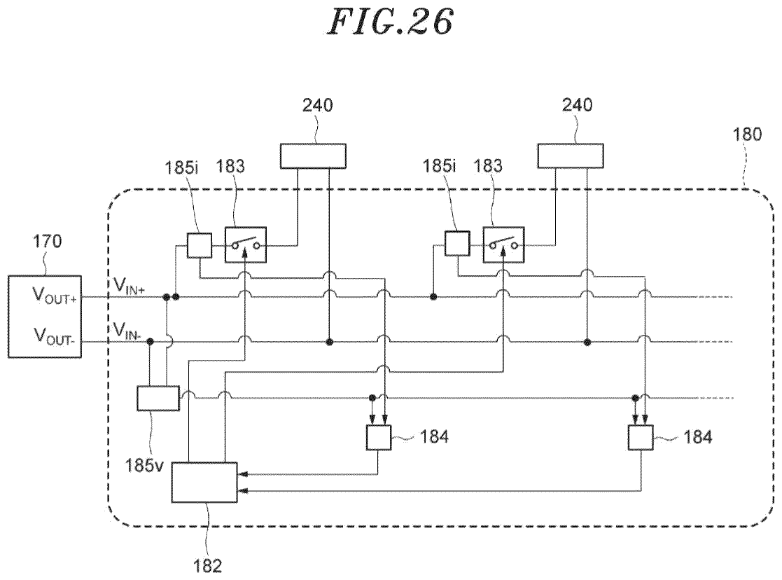

FIG. 3 is a diagram schematically illustrating a plasma processing apparatus according to one exemplary embodiment. A plasma processing apparatus 100A shown in FIG. 3 includes at least one high frequency power supply 300, a power receiving coil unit 140, an electricity storage unit 160, and at least one power consuming member 240 (see FIGS. 25 and 26). The plasma processing apparatus 100A may further include a power transmission unit 120, a power transmitting coil unit 130, a rectifying and smoothing unit 150, a constant voltage controller 180 (an example of a voltage controller), a ground frame 110, and a matching unit 301.

At least one high frequency power supply 300 includes the first RF generator 31a and/or the second RF generator 32a. At least one high frequency power supply 300 is electrically connected to the substrate support 11 via the matching unit 301. The matching unit 301 includes at least one impedance matching circuit.

The ground frame 110 includes the chamber 10 and is electrically grounded. The ground frame 110 electrically separates an internal space 110h (RF-Hot space) from an external space 110a (atmospheric space). The ground frame 110 surrounds the substrate support 11 disposed within the space 110h. In the plasma processing apparatus 100A, the rectifying and smoothing unit 150, the electricity storage unit 160, and the constant voltage controller 180 are disposed within the space 110h. In the plasma processing apparatus 100A, the power transmission unit 120, the power transmitting coil unit 130, and the power receiving coil unit 140 are disposed within the space 110a.

The devices disposed within the space 110a, that is, the power transmission unit 120, the power transmitting coil unit 130, and the power receiving coil unit 140, are covered by a metal housing made of a metal such as aluminum, and the metal housing is grounded. Thereby, this suppresses leakage of high frequency noise caused by high frequency power such as a first RF signal and/or a second RF signal. The metal housing and each power feeding line have an insulating distance therebetween. In the following description, high frequency power such as the first RF signal and/or the second RF signal propagating toward the power transmission unit 120 may be referred to as high frequency noise, common-mode noise, or conductive noise.

The power transmission unit 120 is electrically connected between an AC power supply 400 (for example, a commercial AC power supply) and the power transmitting coil unit 130. The power transmission unit 120 receives the frequency of AC power from the AC power supply 400 and converts the frequency of the AC power into a transmission frequency, thereby generating AC power having the transmission frequency, that is, transmission AC power.

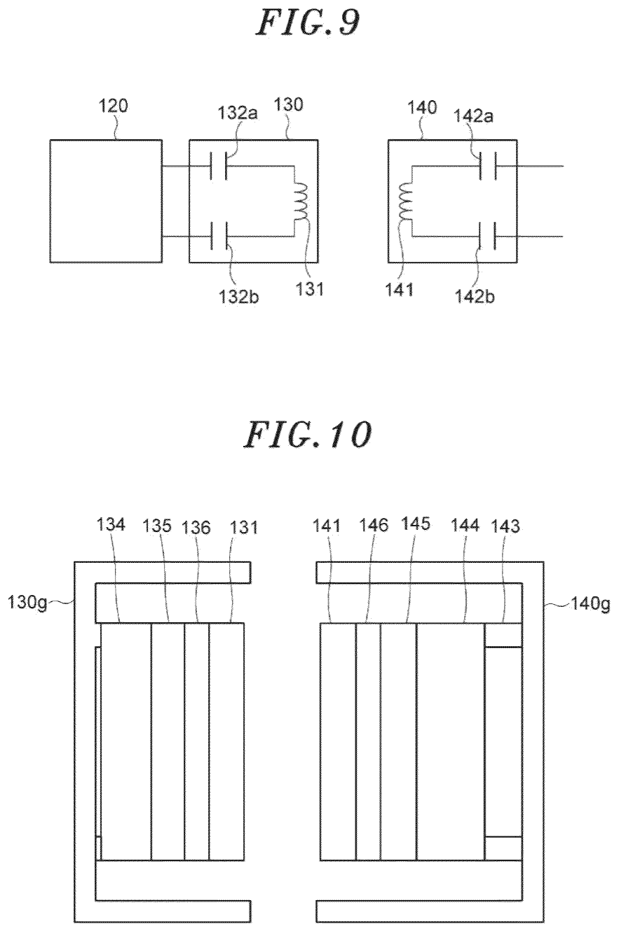

The power transmitting coil unit 130 includes a power transmitting coil 131 (see FIG. 9), which will be described later. The power transmitting coil 131 is electrically connected to power transmission unit 120. The power transmitting coil 131 receives the transmission AC power from the power transmission unit 120 and wirelessly transmits the transmission AC power to a power receiving coil 141.

The power receiving coil unit 140 includes a power receiving coil 141 (see FIG. 9) which will be described later. The power receiving coil 141 is electromagnetically inductively coupled to the power transmitting coil 131. Electromagnetic induction coupling includes magnetic field coupling and electric field coupling. In addition, the magnetic field coupling includes magnetic resonance. The distance between the power receiving coil 141 and the power transmitting coil 131 is set so as to suppress common mode noise (conductive noise). Further, the distance between the power receiving coil 141 and the power transmitting coil 131 is set to a distance that allows power feeding. The distance between the power receiving coil 141 and the power transmitting coil 131 is set so that the attenuation of high frequency power (that is, high frequency noise) between the power receiving coil 141 and the power transmitting coil 131 is below a threshold value and so that power from the power transmitting coil 131 is received by the power receiving coil 141. The threshold value of the attenuation is set to a value that may sufficiently prevent damage or malfunction of the power transmission unit 120. The threshold value of the attenuation is, for example, −20 dB. The transmission AC power received by the power receiving coil unit 140 is output to the rectifying and smoothing unit 150.

The rectifying and smoothing unit 150 is electrically connected between the power receiving coil unit 140 and the electricity storage unit 160. The rectifying and smoothing unit 150 generates DC power by full-wave rectification and smoothing of the AC power transmitted from the power receiving coil unit 140. The DC power generated by the rectifying and smoothing unit 150 is stored in the electricity storage unit 160. The electricity storage unit 160 is electrically connected between the rectifying and smoothing unit 150 and the constant voltage controller 180. The rectifying and smoothing unit 150 may generate DC power by half-wave rectification and smoothing of the AC power transmitted from the power receiving coil unit 140.

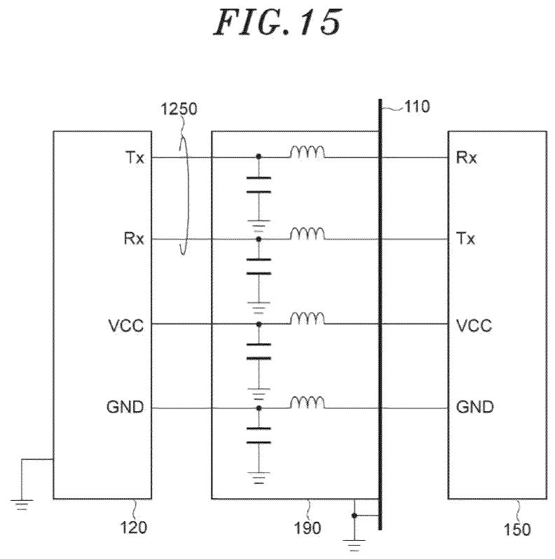

The rectifying and smoothing unit 150 and the power transmission unit 120 are electrically connected to each other by a signal line 1250. The rectifying and smoothing unit 150 transmits an instruction signal to the power transmission unit 120 via the signal line 1250. The instruction signal is a signal for instructing the power transmission unit 120 to supply transmission AC power or to stop supplying transmission AC power. The instruction signal may include a status signal, an abnormality detection signal, and a cooling control signal for the power transmitting coil unit 130 and the power receiving coil unit 140. The status signal is a value of the magnitude and/or phase of the voltage, current, power, etc. detected by a voltage detector 155v (see FIG. 14) and a current detector 155i (see FIG. 14) of the rectifying and smoothing unit 150. The abnormality detection signal is a signal for transmitting to the power transmission unit 120 the occurrence of a failure and/or an abnormal temperature in the rectifying and smoothing unit 150. The cooling control signal controls the cooling appliances provided in the power transmitting coil unit 130 and the power receiving coil unit 140. The cooling control signal controls the number of revolutions of a fan in the case of air cooling, for example. Further, in the case of liquid cooling, the flow rate and/or temperature of a coolant are controlled.

The constant voltage controller 180 applies a voltage to at least the power consuming member 240 using the power stored in the electricity storage unit 160. The constant voltage controller 180 may at least control the application of voltage to the power consuming member 240 and the stopping of the application.

In the plasma processing apparatus 100A, the power receiving coil 141 functions as a filter against high frequency noise caused by high frequency power such as the first RF signal and/or the second RF signal. Accordingly, the propagation of high frequency noise to the power supply outside the plasma processing apparatus is suppressed.

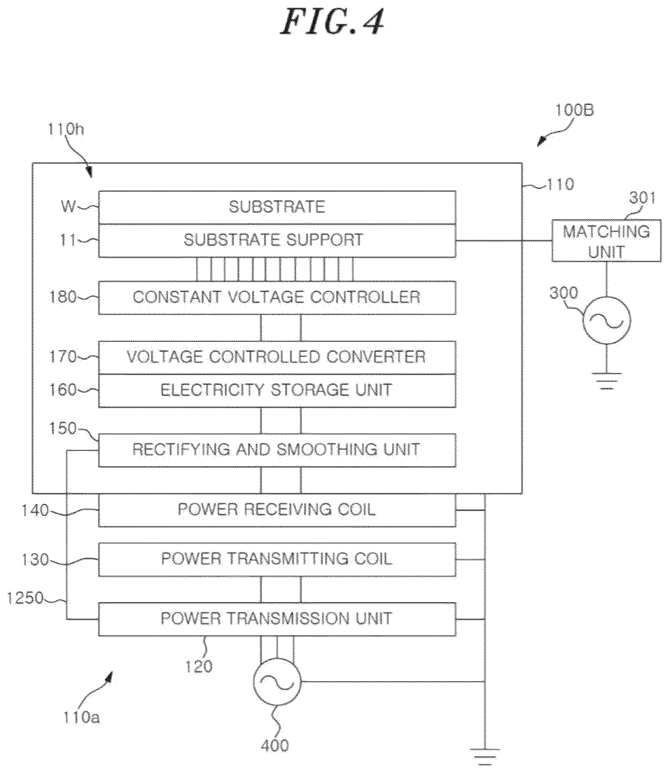

FIG. 4 is referred. FIG. 4 is a diagram schematically illustrating a plasma processing apparatus according to another exemplary embodiment. Hereinafter, a plasma processing apparatus 100B shown in FIG. 4 will be described from the viewpoint of its differences from the plasma processing apparatus 100A.

The plasma processing apparatus 100B further includes a voltage controlled converter 170. The voltage controlled converter 170 is a DC-DC converter, and is connected between the electricity storage unit 160 and the constant voltage controller 180. The voltage controlled converter 170 may be configured to input a constant output voltage to the constant voltage controller 180 even when a voltage fluctuation occurs in the electricity storage unit 160. Further, the voltage fluctuation in the electricity storage unit 160 may occur as a voltage drop or the like according to the stored power when the electricity storage unit 160 is configured with an electric double layer, for example.

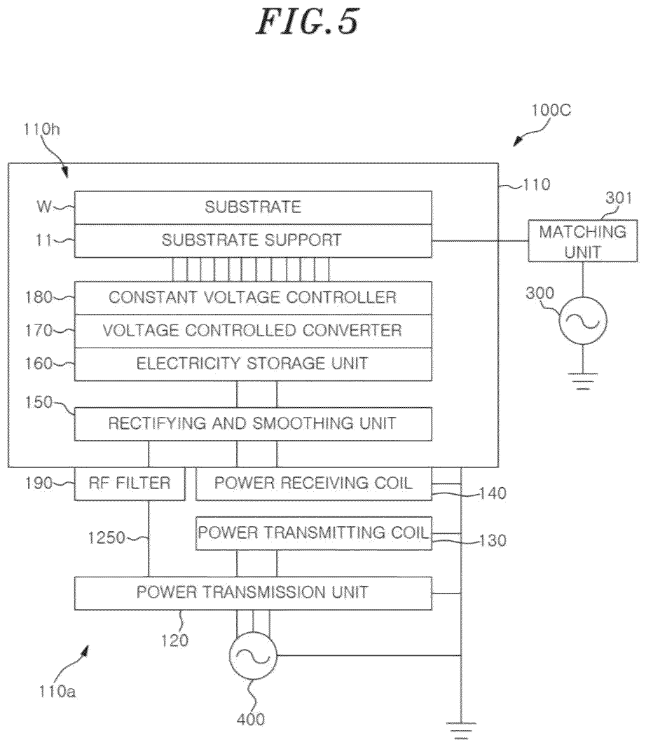

FIG. 5 is referred. FIG. 5 is a diagram schematically illustrating a plasma processing apparatus according to yet another exemplary embodiment. Hereinafter, a plasma processing apparatus 100C shown in FIG. 5 will be described from the viewpoint of its differences from the plasma processing apparatus 100B.

The plasma processing apparatus 100C further includes an RF filter 190. The RF filter 190 is connected between the rectifying and smoothing unit 150 and the power transmission unit 120. The RF filter 190 configures a portion of the signal line 1250. The RF filter 190 has the characteristic of suppressing the propagation of high frequency power (high frequency noise) via the signal line 1250. That is, the RF filter 190 includes a low-pass filter having a characteristic of having high impedance to high frequency noise (conductive noise) but passing an instruction signal of a relatively low frequency.

In the plasma processing apparatus 100C, the electricity storage unit 160, the voltage controlled converter 170, and the constant voltage controller 180 are integrated with one another. That is, the electricity storage unit 160, the voltage controlled converter 170, and the constant voltage controller 180 are all disposed within a single metal housing or formed on a single circuit board. This shortens the length of each of a pair of power feeding lines (positive line and negative line) connecting the electricity storage unit 160 and the voltage controlled converter 170 to each other. Furthermore, the lengths of the pair of power feeding lines connecting the electricity storage unit 160 and the voltage controlled converter 170 to each other may be made equal to each other. Furthermore, the length of each of the pair of power feeding lines (positive and negative lines) connecting the voltage controlled converter 170 and the constant voltage controller 180 to each other is shortened. Furthermore, the lengths of the pair of power feeding lines connecting the voltage controlled converter 170 and the constant voltage controller 180 to each other may be made equal to each other. Accordingly, malfunction and damage of a device caused by normal mode noise (voltage difference between lines of the positive and negative lines) is suppressed. When another metal body that shields the electromagnetic field is provided around a housing within the chamber 10, a single housing does not have to be made of metal.

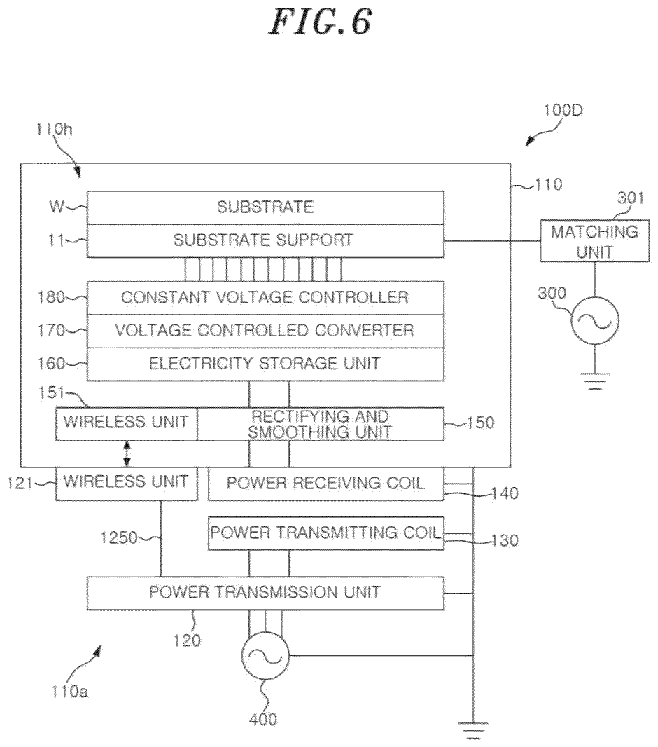

FIG. 6 is referred. FIG. 6 is a diagram schematically illustrating a plasma processing apparatus according to yet another exemplary embodiment. Hereinafter, a plasma processing apparatus 100D shown in FIG. 6 will be described from the viewpoint of its differences from the plasma processing apparatus 100C.

The plasma processing apparatus 100 D does not include the RF filter 190. In the plasma processing apparatus 100D, the rectifying and smoothing unit 150 includes a communication unit 151 which is a wireless unit. The power transmission unit 120 also includes a communication unit 121 which is a wireless unit. The aforementioned instruction signal is transmitted between the rectifying and smoothing unit 150 and the power transmission unit 120 using the communication unit 151 and the communication unit 121. The communication units 121 and 151 will be described in detail later.

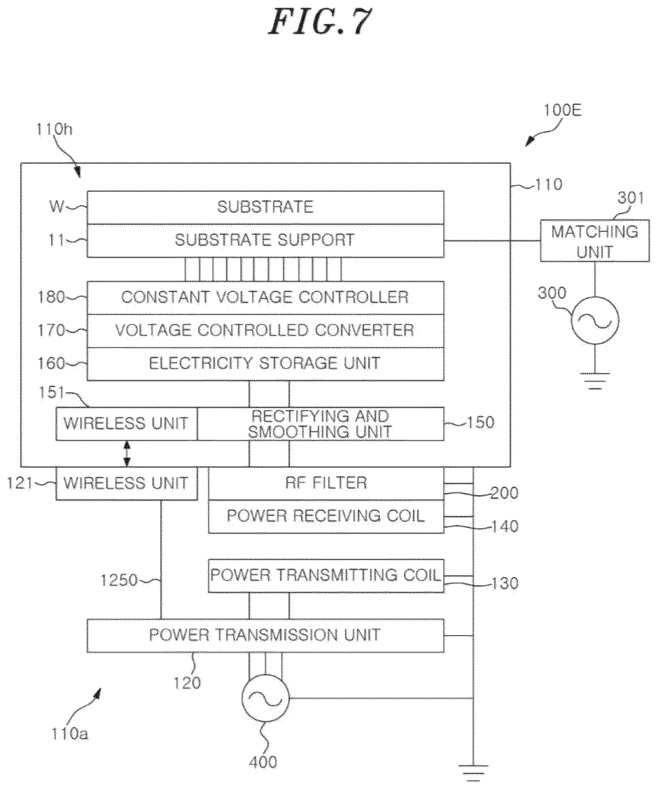

FIG. 7 is referred. FIG. 7 is a diagram schematically illustrating a plasma processing apparatus according to yet another exemplary embodiment. Hereinafter, a plasma processing apparatus 100E shown in FIG. 7 will be described from the viewpoint of its differences from the plasma processing apparatus 100D.

The plasma processing apparatus 100E further includes an RF filter 200. The RF filter 200 is connected between the power receiving coil unit 140 and the rectifying and smoothing unit 150. The RF filter 200 has the characteristic of reducing or blocking high frequency noise propagating from the power receiving coil unit 140 to the power transmitting coil 131 and the power transmission unit 120. The RF filter 200 will be described in detail later.

Hereinafter, configurations of each portion for wireless power feeding in the plasma processing apparatuses according to various exemplary embodiments will be described in detail.

### Configuration of Power Transmission Unit

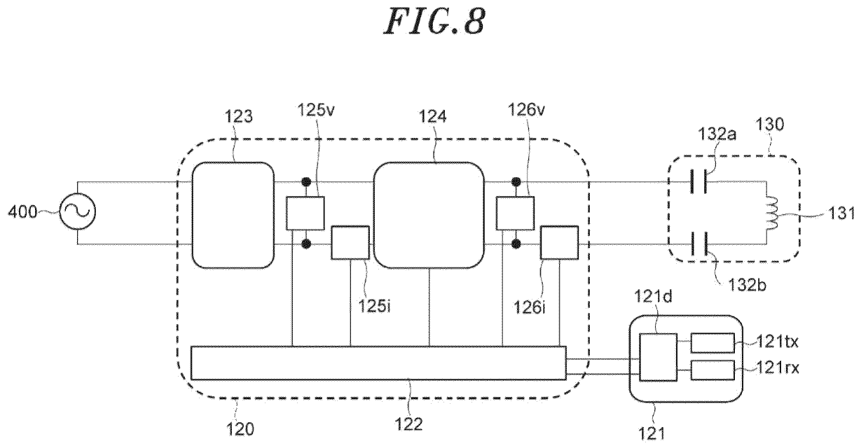

FIG. 8 is a diagram illustrating a power transmission unit according to one exemplary embodiment. As described above, the power transmission unit 120 receives the frequency of the AC power from the AC power supply 400 and converts the frequency of the AC power into a transmission frequency, thereby generating transmission AC power having the transmission frequency.

In one embodiment, the power transmission unit 120 includes a controller 122, a rectifying and smoothing unit 123, and an inverter 124. The controller 122 is configured of a processor such as a CPU or a programmable logic device such as a field-programmable gate array (FPGA).

The rectifying and smoothing unit 123 includes a rectifying circuit and a smoothing circuit (ripple filter). The rectifying circuit includes, for example, a diode bridge. The smoothing circuit includes, for example, an interline capacitor. The rectifying and smoothing unit 123 generates DC power by full-wave rectification and smoothing of the AC power from the AC power supply 400. Further, the rectifying and smoothing unit 123 may generate DC power by half-wave rectification and smoothing of the AC power from the AC power supply 400.

The inverter 124 generates transmission AC power having a transmission frequency from the DC power output by the rectifying and smoothing unit 123. The inverter 124 is, for example, a full-bridge inverter, and includes a plurality of triacs or a plurality of switching elements (for example, FETs). The inverter 124 generates the transmission AC power by ON/OFF control of the plurality of triacs or the plurality of switching elements by the controller 122. The transmission AC power output from the inverter 124 is output to the power transmitting coil unit 130.

The power transmission unit 120 may further include a voltage detector 125v, a current detector 125i, a voltage detector 126v, and a current detector 126i. The voltage detector 125v detects a voltage value between the pair of power feeding lines that connect the rectifying and smoothing unit 123 and the inverter 124 to each other. The current detector 125i detects a current value between the rectifying and smoothing unit 123 and the inverter 124. The voltage detector 126v detects a voltage value between the pair of power feeding lines that connect the inverter 124 and the power transmitting coil unit 130 to each other. The current detector 126i detects a current value between the inverter 124 and the power transmitting coil unit 130. The controller 122 is notified of the voltage value detected by the voltage detector 125v, the current value detected by the current detector 125i, the voltage value detected by the voltage detector 126v, and the current value detected by the current detector 126i.

The power transmission unit 120 includes the communication unit 121 described above. The communication unit 121 includes a driver 121d, a transmitter 121tx, and a receiver 121rx. The transmitter 121tx is a transmitter of a wireless signal or a transmitter of an optical signal. The receiver 121rx is a receiver of a wireless signal or a receiver of an optical signal. The communication unit 121 drives the transmitter 121tx using the driver 121d to output the signal from the controller 122 from the transmitter 121tx as a wireless signal or an optical signal. The signal output from the transmitter 121tx is received by the communication unit 151 (see FIG. 14) which will be described later. Furthermore, the communication unit 121 receives a signal such as the instruction signal described above from the communication unit 151 by the receiver 121rx, and inputs the received signal to the controller 122 via the driver 121d. The controller 122 switches between outputting and stopping the transmission AC power by controlling the inverter 124 in accordance with the instruction signal received from the communication unit 151 via the communication unit 121, the voltage value detected by the voltage detector 125v, the current value detected by the current detector 125i, the voltage value detected by the voltage detector 126v, and the current value detected by the current detector 126i.

### Power Transmitting Coil Unit and Power Receiving Coil Unit

FIGS. 9 to 11 are referred. Each of FIGS. 9 to 11 is a diagram illustrating a power transmitting coil unit and a power receiving coil unit according to one exemplary embodiment. As shown in FIG. 9, the power transmitting coil unit 130 may include, in addition to the power transmitting coil 131, a resonant capacitor 132a and a resonant capacitor 132b. The resonant capacitor 132a is connected between one of the pair of power feeding lines that connect the power transmission unit 120 and the power transmitting coil unit 130 to each other and one end of the power transmitting coil 131. The resonant capacitor 132b is connected between the other of the pair of power feeding lines and the other end of the power transmitting coil 131. The power transmitting coil 131, the resonant capacitor 132a, and the resonant capacitor 132b configure a resonant circuit for the transmission frequency. That is, the power transmitting coil 131, the resonant capacitor 132a, and the resonant capacitor 132b have a resonant frequency that is approximately equal to the transmission frequency. Further, the power transmitting coil unit 130 does not necessarily have to include either the resonant capacitor 132a or the resonant capacitor 132b.

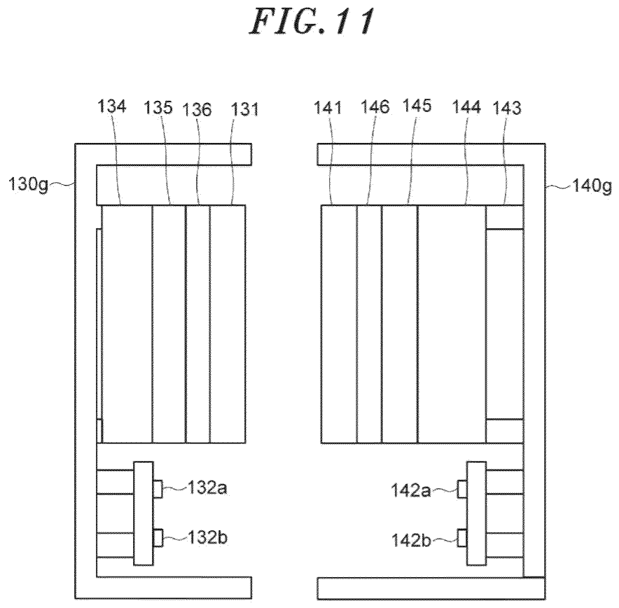

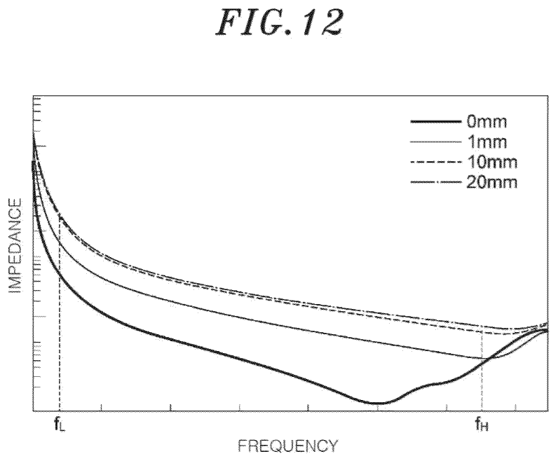

As shown in FIGS. 10 and 11, the power transmitting coil unit 130 may further include a metal housing 130g. The metal housing 130g has an open end and is grounded. The power transmitting coil 131 is disposed within the metal housing 130g with an insulation distance secured therebetween. The power transmitting coil unit 130 may further include a heat sink 134, a ferrite material 135, and a thermally conductive sheet 136. The heat sink 134 is disposed within the metal housing 130g and is supported by the metal housing 130g. The ferrite material 135 is disposed on the heat sink 134. The thermally conductive sheet 136 is disposed on the ferrite material 135. The power transmitting coil 131 is disposed on the thermally conductive sheet 136 and faces the power receiving coil 141 via the open end of the metal housing 130g. As shown in FIG. 11, the resonant capacitor 132a and the resonant capacitor 132b may be further accommodated within the metal housing 130g.

As shown in FIG. 9, the power receiving coil unit 140 includes the power receiving coil 141. The power receiving coil 141 is electromagnetically inductively coupled to the power transmitting coil 131. The power receiving coil unit 140 may include, in addition to the power receiving coil 141, a resonant capacitor 142a and a resonant capacitor 142b. The resonant capacitor 142a is connected between one of the pair of power feeding lines extending from the power receiving coil unit 140 and one end of the power receiving coil 141. The resonant capacitor 142b is connected between the other of the pair of power feeding lines and the other end of the power receiving coil 141. The power receiving coil 141, the resonant capacitor 142a, and the resonant capacitor 142b configure a resonant circuit for the transmission frequency. That is, the power receiving coil 141, the resonant capacitor 142a, and the resonant capacitor 142b have a resonant frequency that is approximately equal to the transmission frequency. Further, the power receiving coil unit 140 does not necessarily have to include either the resonant capacitor 142a or the resonant capacitor 142b.

As shown in FIGS. 10 and 11, the power receiving coil unit 140 may further include a metal housing 140g. The metal housing 140g has an open end and is grounded. The power receiving coil 141 is disposed within the metal housing 140g with an insulation distance secured therebetween. The power receiving coil unit 140 may further include a spacer 143, a heat sink 144, a ferrite material 145, and a thermally conductive sheet 146. The spacer 143 is disposed within the metal housing 140g and is supported by the metal housing 140g. The spacer 143 will be described later. The heat sink 144 is disposed on the spacer 143. The ferrite material 145 is disposed on the heat sink 144. The thermally conductive sheet 146 is disposed on the ferrite material 145. The power receiving coil 141 is disposed on the thermally conductive sheet 146 and faces the power transmitting coil 131 via the open end of the metal housing 140g. As shown in FIG. 11, the resonant capacitor 142a and the resonant capacitor 142b may be further accommodated within the metal housing 140g.

The spacer 143 is made of a dielectric material and is provided between the power receiving coil 141 and the metal housing 140g (ground). The spacer 143 provides a space stray capacitance between the power receiving coil 141 and the ground.

### Impedance Characteristics of Power Receiving Coil Unit

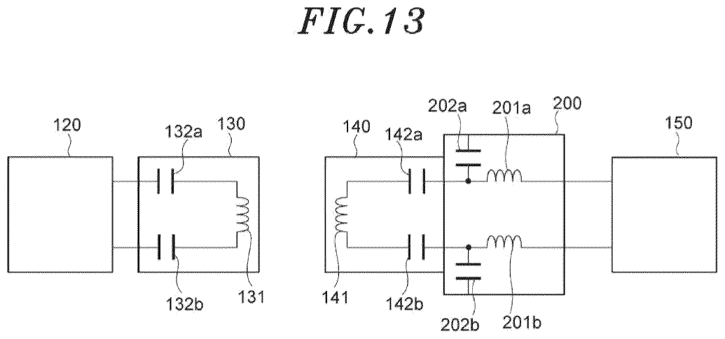

FIG. 12 is referred. FIG. 12 is a graph showing the impedance characteristics of a power receiving coil unit according to one exemplary embodiment. FIG. 12 shows the impedance characteristics of the power receiving coil unit 140 according to the thickness of the spacer 143. The thickness of the spacer 143 corresponds to the distance between the heat sink 144 and the metal housing 140g. As shown in FIG. 12, the power receiving coil unit 140 may adjust the impedance of each of frequencies f_{H} and f_{L} in accordance with the thickness of the spacer 143. Accordingly, the power receiving coil unit 140 may provide high impedance at each of the frequencies of two high frequency powers used in the plasma processing apparatus, such as the first RF signal and the second RF signal. Furthermore, since a high impedance may be obtained in the power receiving coil unit 140, the loss of high frequency power may be suppressed and a high processing rate (for example, an etching rate) may be obtained.

### RF Filter 200

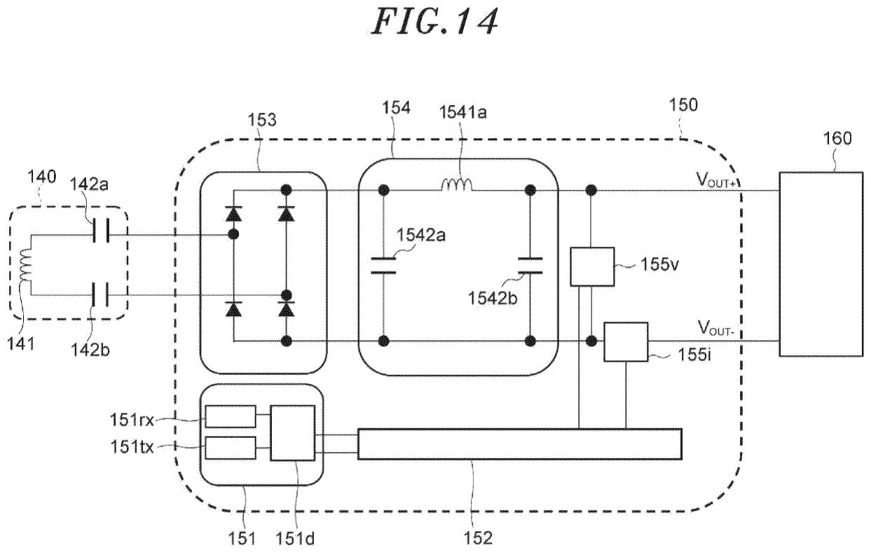

FIG. 13 is referred. FIG. 13 is a diagram illustrating an RF filter according to one exemplary embodiment. As shown in FIG. 13, the RF filter 200 is connected between the power receiving coil unit 140 and the rectifying and smoothing unit 150. The RF filter 200 includes an inductor 201a, an inductor 201b, a termination capacitor 202a, and a termination capacitor 202b. One end of the inductor 201a is connected to the resonant capacitor 142a, and the other end of the inductor 201a is connected to the rectifying and smoothing unit 150. One end of the inductor 201b is connected to the resonant capacitor 142b, and the other end of the inductor 201b is connected to the rectifying and smoothing unit 150. The termination capacitor 202a is connected between one end of the inductor 201a and the ground. The termination capacitor 202b is connected between one end of the inductor 201b and the ground. The inductor 201a and the termination capacitor 202a form a low pass filter. Additionally, the inductor 201b and the termination capacitor 202b form a low pass filter. The RF filter 200 makes it possible to obtain a high impedance at each of the frequencies of the two high frequency powers used in the plasma processing apparatus, such as the first RF signal and the second RF signal.

Accordingly, the loss of high frequency power may be suppressed, and a high processing rate (for example, etching rate) may be obtained.

### Rectifying and Smoothing Unit

FIG. 14 is referred. FIG. 14 is a diagram illustrating a rectifying and smoothing unit according to one exemplary embodiment. In one embodiment, the rectifying and smoothing unit 150 includes a controller 152, a rectifying circuit 153, and a smoothing circuit 154. The rectifying circuit 153 is connected between the power receiving coil unit 140 and the smoothing circuit 154. The smoothing circuit 154 is connected between the rectifying circuit 153 and the electricity storage unit 160. The controller 152 is configured of a processor such as a CPU or a programmable logic device such as an FPGA. Further, the controller 152 may be the same as or different from the controller 122.

The rectifying circuit 153 outputs power generated by full-wave rectification of the AC power from the power receiving coil unit 140. The rectifying circuit 153 is, for example, a diode bridge. Further, the rectifying circuit 153 may output power generated by half-wave rectification of the AC power from the power receiving coil unit 140.

The smoothing circuit 154 generates DC power by smoothing the power from the rectifying circuit 153. The smoothing circuit 154 may include an inductor 1541a, a capacitor 1542a, and a capacitor 1542b. One end of the inductor 1541a is connected to one of a pair of inputs of the smoothing circuit 154. The other end of the inductor 1541a is connected to a positive output (V_{OUT+}) of the rectifying and smoothing unit 150. The positive output of the rectifying and smoothing unit 150 is connected to one end of each of one or more capacitors of the electricity storage unit 160 via a positive line 160p (see FIGS. 23A and 23B) of the pair of power feeding lines described below.

One end of the capacitor 1542a is connected to one of the pair of inputs of the smoothing circuit 154 and one end of the inductor 1541a. The other end of the capacitor 1542a is connected to the other of a pair of outputs of the smoothing circuit 154 and a negative output (V_{OUT-}) of the rectifying and smoothing unit 150. The negative output of the rectifying and smoothing unit 150 is connected to the other end of each of one or more capacitors of the electricity storage unit 160 via a negative line 160m (see FIGS. 23A and 23B) of the pair of power feeding lines described below. One end of the capacitor 1542b is connected to the other end of the inductor 1541a. The other end of the capacitor 1542b is connected to the other of the pair of outputs of the smoothing circuit 154 and the negative output (V_{OUT-}) of the rectifying and smoothing unit 150.

The rectifying and smoothing unit 150 may further include a voltage detector 155v and a current detector 155i. The voltage detector 155v detects a voltage value between the positive output and the negative output of the rectifying and smoothing unit 150. The current detector 155i detects a current value between the rectifying and smoothing unit 150 and the electricity storage unit 160. The voltage value detected by the voltage detector 155v and the current value detected by the current detector 155i are notified to the controller 152. The controller 152 generates the instruction signal described above in accordance with the power stored in the electricity storage unit 160. For example, when the power stored in the electricity storage unit 160 is equal to or less than a first threshold value, the controller 152 generates an instruction signal to instruct the power transmission unit 120 to feed power, that is, to output transmission AC power. The first threshold value is the power consumption at a load, for example, the power consuming member 240. In addition, considering margin, the power consumption of a load such as the power consuming member 240 may be multiplied by a certain value (for example, a value within the range of 1 to 3). When the power stored in the electricity storage unit 160 is greater than a second threshold value, the controller 152 generates an instruction signal to instruct the power transmission unit 120 to stop feeding power, that is, to stop outputting the transmission AC power. The second threshold value is a value that does not exceed limit electricity storage power of the electricity storage unit 160. The second threshold value is, for example, a value obtained by multiplying the limit electricity storage power of the electricity storage unit 160 by a certain value (for example, a value equal to or less than 1).

The rectifying and smoothing unit 150 includes the communication unit 151 described above. The communication unit 151 includes a driver 151d, a transmitter 151tx, and a receiver 151rx. The transmitter 151tx is a transmitter of a wireless signal or a transmitter of an optical signal. The receiver 151rx is a receiver of a wireless signal or a receiver of an optical signal. The communication unit 151 drives the transmitter 151tx by the driver 151d to output a signal from the controller 122, such as an instruction signal, from the transmitter 151tx as a wireless signal or an optical signal. The signal output from the transmitter 151tx is received by the communication unit 121 of the power transmission unit 120. Furthermore, the communication unit 151 receives a signal from the communication unit 121 by the receiver 151rx, and inputs the received signal to the controller 152 via the driver 151d.

### RF Filter 190

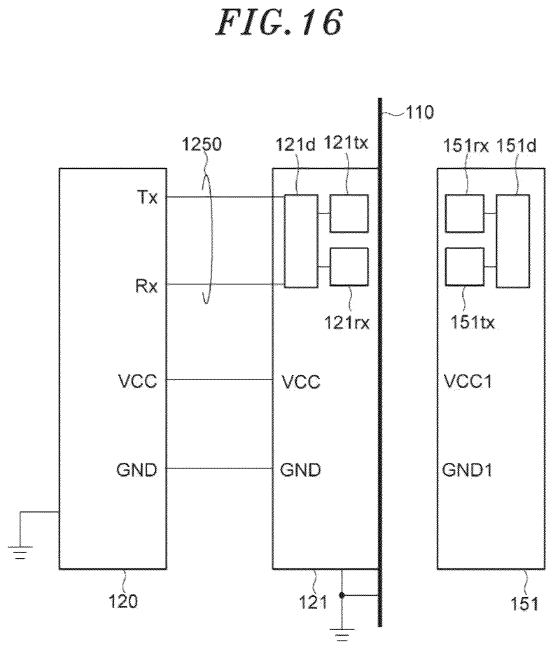

FIG. 15 is referred. FIG. 15 is a diagram illustrating the RF filter 190 according to one exemplary embodiment. As shown in FIG. 15, the signal line 1250 may include a first signal line electrically connecting a signal output (Tx) of the power transmission unit 120 and a signal input (Rx) of the rectifying and smoothing unit 150, and a second signal line electrically connecting the signal input (Rx) of the power transmission unit 120 and the signal output (Tx) of the rectifying and smoothing unit 150. The signal line 1250 may include a signal line connecting a first reference voltage terminal (VCC) of the power transmission unit 120 and the first reference voltage terminal (VCC) of the rectifying and smoothing unit 150, and a signal line connecting a second reference voltage terminal (GND) of the power transmission unit 120 and the second reference voltage terminal (GND) of the rectifying and smoothing unit 150. The signal line 1250 may be a shielded cable covered with a shield at ground potential. In this connection, a plurality of signal lines constituting the signal line 1250 may be individually covered with a shield or may be collectively covered with a shield. The RF filter 190 provides a low pass filter for each of the plurality of signal lines constituting the signal line 1250. The low pass filter may be an LC filter including an inductor and a capacitor. The inductor of the low pass filter forms a portion of the corresponding signal line. The capacitor is connected between one end of the inductor connected to the power transmission unit 120 and the ground. The RF filter 190 makes it possible to suppress the propagation of high frequency power (high frequency noise) via the signal line 1250 between the rectifying and smoothing unit 150 and the power transmission unit 120.

### Communication Unit of Power Transmission Unit and Communication Unit of Rectifying and Smoothing Unit

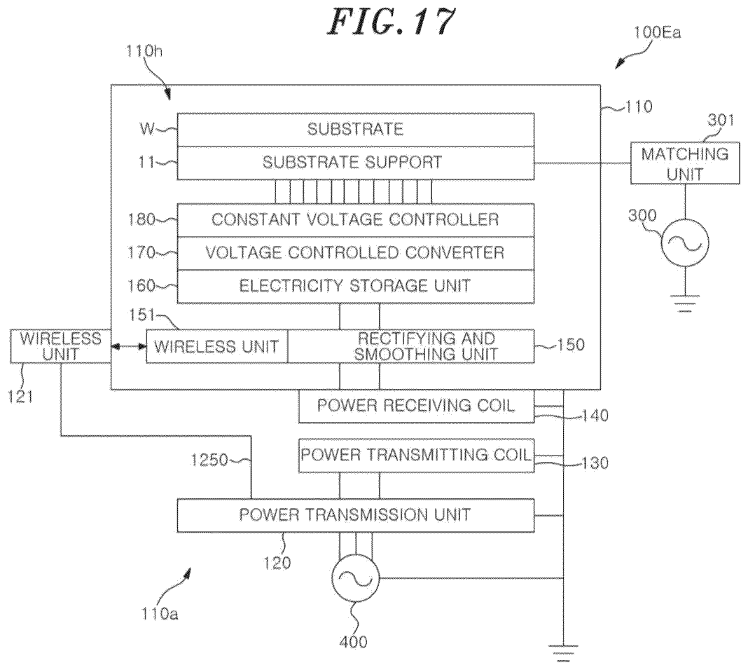

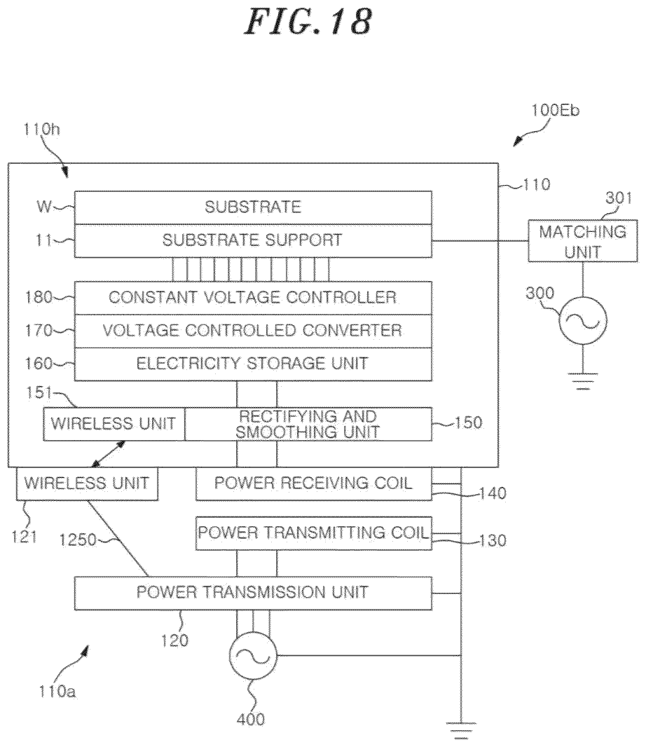

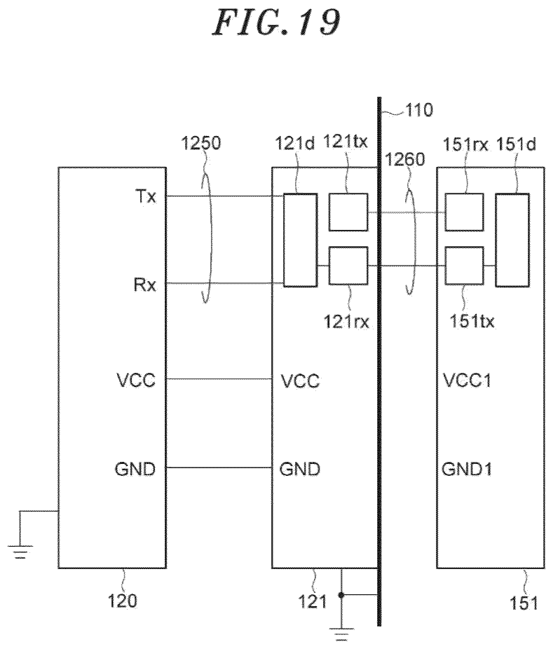

FIGS. 16 to 18 are referred. FIG. 16 is a diagram illustrating a communication unit of a power transmission unit and a communication unit of a rectifying and smoothing unit according to one exemplary embodiment. Each of FIGS. 17 and 18 is a diagram schematically illustrating a plasma processing apparatus according to yet another exemplary embodiment. As shown in FIGS. 6, 7, 16, 17, and 18, the communication unit 121 and the communication unit 151 may be configured to transmit signals such as the instruction signal described above between each other via wireless communication. The communication via wireless communication may be performed by optical communication. When the communication unit 121 and the communication unit 151 transmit signals therebetween via wireless communication, the communication unit 121 and the communication unit 151 may be disposed in any location as long as there is no shielding material interposed therebetween. According to the examples shown in these drawings, the RF filter 190 is not required. Further, in various exemplary embodiments including the examples shown in FIGS. 16 to 18, the signal line 1250 may be a shielded cable covered with a shield at ground potential. In this connection, the plurality of signal lines constituting the signal line 1250 may be individually covered with a shield or may be collectively covered with a shield.

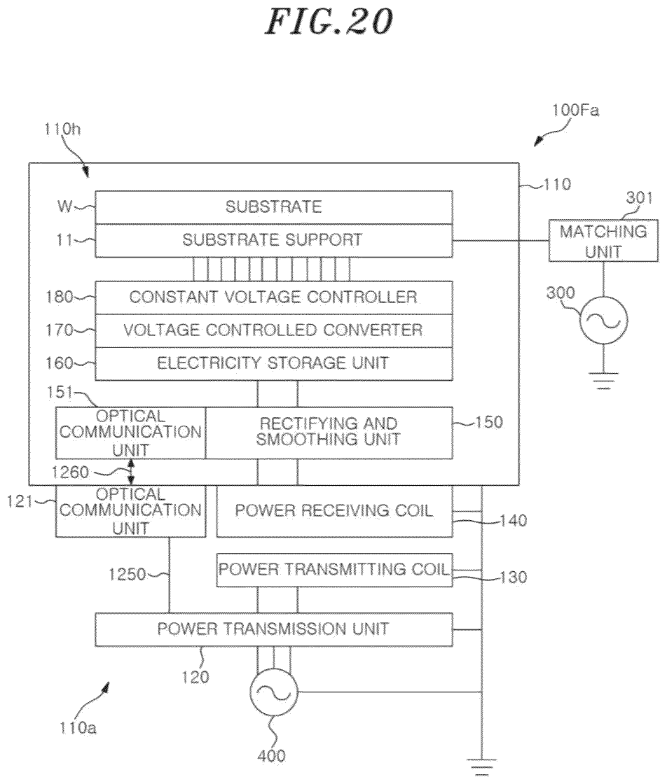

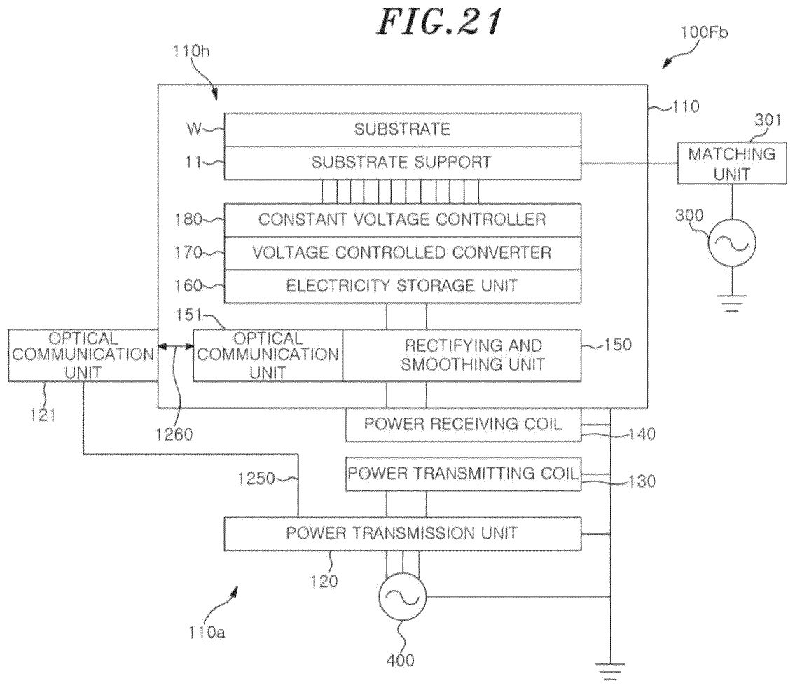

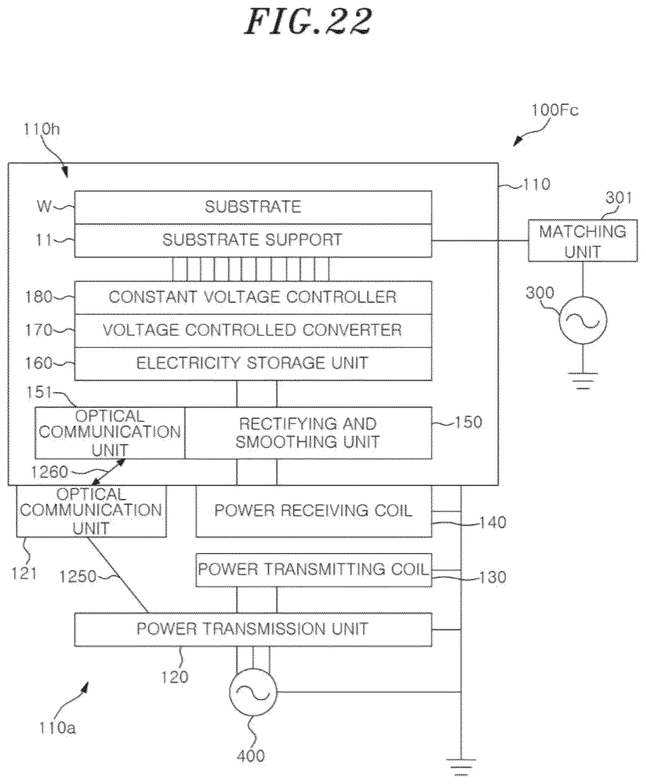

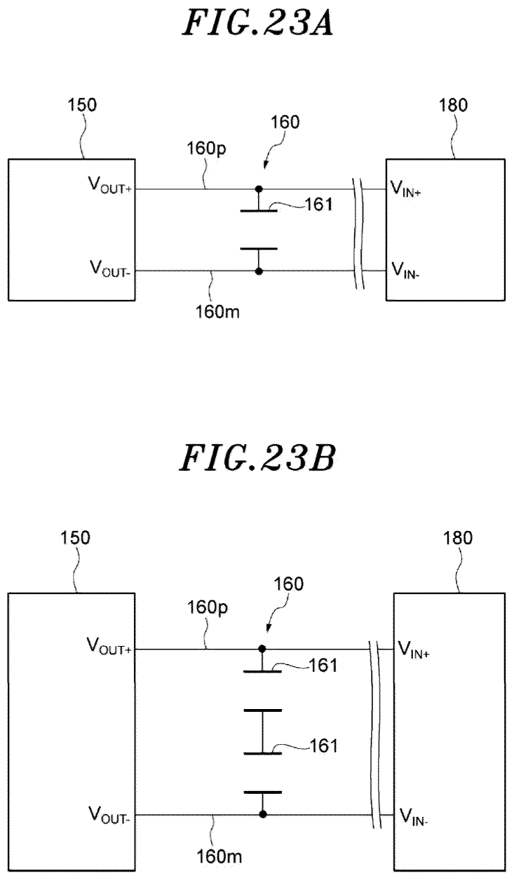

FIGS. 19 to 22 are referred. FIG. 19 is a diagram illustrating a communication unit of a power transmission unit and a communication unit of a rectifying and smoothing unit according to another exemplary embodiment. Each of FIGS. 20 to 22 is a diagram schematically illustrating a plasma processing apparatus according to yet another exemplary embodiment. As shown in FIGS. 19 to 22, the communication unit 121 and the communication unit 151 may be configured to transmit signals (optical signals) such as the above-mentioned instruction signal between each other via an optical fiber 1260, that is, by optical fiber communication. When the communication unit 121 and communication unit 151 transmit signals therebetween via the optical fiber 1260, the communication unit 121 and the communication unit 151 may be disposed in any location as long as the bending radius of the optical fiber 1260 falls within the allowable range. Also in the examples shown in these drawings, the RF filter 190 becomes unnecessary.

### Electricity Storage Unit

FIGS. 23A and 23B are referred. Each of FIGS. 23A and 23B is a diagram illustrating an electricity storage unit according to one exemplary embodiment. As shown in FIG. 23A, the electricity storage unit 160 includes a capacitor 161. The capacitor 161 is connected between the pair of power feeding lines, that is, the positive line 160p and the negative line 160m. The positive line 160p extends from the positive output (V_{OUT+}) of the rectifying and smoothing unit 150 toward a load. The negative line 160m extends from the negative output (V_{OUT-}) of the rectifying and smoothing unit 150 toward the load. The capacitor 161 may be a polarized capacitor. The capacitor 161 may be an electric double layer or lithium ion battery.

As shown in FIG. 23B, the electricity storage unit 160 may include a plurality of capacitors 161. The plurality of capacitors 161 are connected in series between the positive line 160p and the negative line 160m. The plurality of capacitors 161 may have the same capacitance or may have different capacitances. Each of the plurality of capacitors 161 may be a polarized capacitor. Each of the plurality of capacitors 161 may be an electric double layer or a lithium ion battery. The electricity storage unit 160 needs to be used under conditions in which a total value of the input voltage thereto and the line-to-line potential difference due to normal mode noise is lower than the allowable input voltage. When the electricity storage unit 160 includes the plurality of capacitors 161 connected in series, the allowable input voltage of the electricity storage unit 160 becomes high. Accordingly, according to the example shown in FIG. 23B, the noise resistance of the electricity storage unit 160 is improved.

### Voltage Controlled Converter

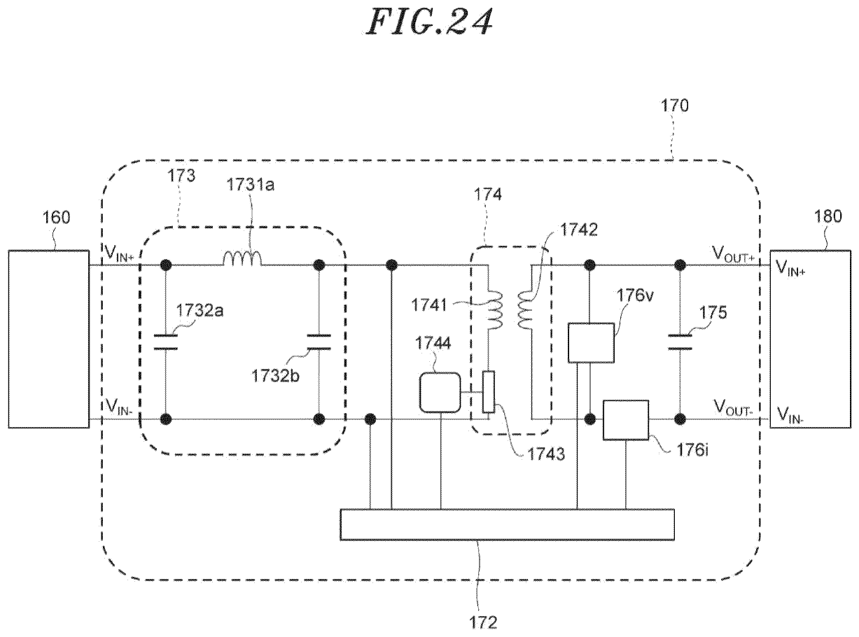

FIG. 24 is referred. FIG. 24 is a diagram illustrating a voltage control converter according to one exemplary embodiment. The voltage controlled converter 170 is a DC-DC converter. The voltage controlled converter 170 is connected between the electricity storage unit 160 and the constant voltage controller 180. The positive line 160p is connected to a positive input (V_{IN+}) of the voltage controlled converter 170. The negative line 160m is connected to a negative input (V_{IN-}) of the voltage controlled converter 170. The positive output (V_{OUT+}) of the voltage controlled converter 170 is connected to the positive input (V_{IN+}) of the constant voltage controller 180. The negative output (V_{OUT-}) of the voltage controlled converter 170 is connected to the negative input (V_{IN-}) of the constant voltage controller 180.

The voltage controlled converter 170 may include a controller 172, a low-pass filter 173, a transformer 174, and a capacitor 175. The low-pass filter 173 may include an inductor 1731a, a capacitor 1732a, and a capacitor 1732b. One end of the inductor 1731a is connected to the positive input (V_{IN+}) of the voltage controlled converter 170. The other end of the inductor 1731a is connected to one end of a primary coil of the transformer 174. One end of the capacitor 1732a is connected to one end of the inductor 1731a and the positive input (V_{IN+}) of the voltage controlled converter 170. The other end of the capacitor 1732a is connected to the negative input (V_{IN-}) of the voltage controlled converter 170. One end of the capacitor 1732b is connected to the other end of the inductor 1731a. The other end of the capacitor 1732b is connected to the negative input (V_{IN-}) of the voltage controlled converter 170.

The transformer 174 includes a primary coil 1741, a secondary coil 1742, and a switch 1743. The other end of the primary coil 1741 is connected to the negative input (V_{IN-}) of the voltage controlled converter 170 via the switch 1743. One end of the secondary coil 1742 is connected to one end of the capacitor 175 and the positive output (V_{OUT+}) of the voltage controlled converter 170. The other end of the secondary coil 1742 is connected to the other end of the capacitor 175 and the negative output (V_{OUT-}) of the voltage controlled converter 170.

A driver 1744 is connected to the switch 1743. The driver 1744 opens and closes the switch 1743. When the switch 1743 is closed, that is, when the other end of the primary coil 1741 and the negative input (V_{IN-}) are in a conductive state, the other end of the primary coil 1741 is connected to the negative input (V_{IN-}) of the voltage controlled converter 170, and DC power from the voltage controlled converter 170 is provided to the constant voltage controller 180. When the switch 1743 is open, that is, when the other end of the primary coil 1741 and the negative input (V_{IN-}) are in a non-conductive state, the connection between the other end of the primary coil 1741 and the negative input (V_{IN-}) of the voltage controlled converter 170 is cut off, and the supply of DC power from the voltage controlled converter 170 to the constant voltage controller 180 is shut off.

The voltage controlled converter 170 may further include a voltage detector 176v and a current detector 176i. The voltage detector 176v detects a voltage value between both ends of the secondary coil 1742 or the voltage value between the positive output and the negative output of the voltage controlled converter 170. The current detector 176i measures a current value between the other end of the secondary coil 1742 and the negative output of the voltage controlled converter 170. The voltage value detected by the voltage detector 176v and the current value detected by the current detector 176i are notified to the controller 172. The controller 172 may be the same as or different from at least one of the controller 122 or the controller 152.

When the voltage value detected by the voltage detector 176v is equal to or higher than the threshold value, the controller 172 controls the driver 1744 to shut off the supply of DC power from the voltage controlled converter 170 to the constant voltage controller 180. The voltage value between the positive output and the negative output of the voltage controlled converter 170 is an added value of the output voltage value of the voltage controlled converter 170 and the line-to-line potential difference due to normal mode noise. In this embodiment, damage to the load of the voltage controlled converter 170 due to an overvoltage caused by the line-to-line potential difference due to normal mode noise may be suppressed.

### Constant Voltage Controller

FIGS. 25 and 26 are referred. FIGS. 25 and 26 are diagrams illustrating a constant voltage controller according to some exemplary embodiments. The constant voltage controller 180 is connected between the electricity storage unit 160 and at least one power consuming member 240, and is configured to control the application of voltage (application of DC voltage) to at least one power consuming member 240 and the stopping of the application.

The constant voltage controller 180 includes a controller 182 and at least one switch 183. The positive input (V_{IN+}) of the constant voltage controller 180 is connected to the power consuming member 240 via the switch 183. The negative input (V_{IN-}) of the constant voltage controller 180 is connected to the power consuming member 240. The switch 183 is controlled by the controller 182. When the switch 183 is closed, the DC voltage from the constant voltage controller 180 is applied to the power consuming member 240. When the switch 183 is open, the application of DC voltage from the constant voltage controller 180 to the power consuming member 240 is stopped. Further, the controller 182 may be the same as or different from at least one of the controller 122, the controller 152, or the controller 172.

In the embodiment shown in FIGS. 25 and 26, the plasma processing apparatus includes a plurality of power consuming members 240. The constant voltage controller 180 includes the controller 182 and a plurality of switches 183. The positive input (V_{IN+}) of the constant voltage controller 180 is connected to the plurality of power consuming members 240 via the plurality of switches 183. The negative input (V_{IN-}) of the constant voltage controller 180 is connected to the plurality of power consuming members 240.

In the embodiment shown in FIGS. 25 and 26, the plurality of power consuming members 240 may include a plurality of heaters (resistive heating elements). The plurality of heaters may be provided within the substrate support 11. In the embodiment shown in FIG. 25, a plurality of resistors 260 are disposed adjacent to each of the plurality of heaters. Each of the plurality of resistors 260 has a resistance value that changes with temperature. Each of the plurality of resistors 260 is, for example, a thermistor. Each of the plurality of resistors 260 is connected in series with a reference resistor (not shown). The constant voltage controller 180 includes a plurality of measuring units 184. Each of the plurality of measuring units 184 applies a reference voltage to a series connection of a corresponding resistor among the plurality of resistors 260 and the reference resistor, and detects the voltage value between both ends of the resistor. Each of the plurality of measuring units 184 notifies the controller 182 of the detected voltage value. The controller 182 specifies the temperature of an area in which the corresponding heater among the plurality of heaters is disposed from the notified voltage value, and controls the application of DC voltage to the corresponding heater so as to bring the temperature of the area closer to the target temperature. Further, instead of the plurality of resistors 260, an optical fiber thermometer may be disposed. In this connection, wiring between the plurality of resistors 260 and the plurality of measuring units 184 is not required, so the influence of high frequency conductive noise on the power consuming member 240 may be eliminated.

In the embodiment shown in FIG. 26, the constant voltage controller 180 includes a voltage detector 185v and a plurality of current detectors 185i. The voltage detector 185v detects the voltage value applied to each of the plurality of heaters. The plurality of current detectors 185i measure the value of the current supplied to the corresponding one of the plurality of heaters, that is, the current value. The plurality of measuring units 184 specifies the resistance value of the corresponding one of the plurality of heaters from the current value detected by the corresponding one of the plurality of current detectors 185i and the voltage value detected by the voltage detector 185v. The controller 182 specifies the temperature of each of a plurality of areas in which each of the plurality of heaters are disposed, based on the detected resistance value of each of the plurality of heaters. The controller 182 controls the application of DC voltage to each of the plurality of heaters so that the temperature of each of the plurality of areas approaches the target temperature.

### Method for Controlling Power Storage Amount of Electricity Storage Unit

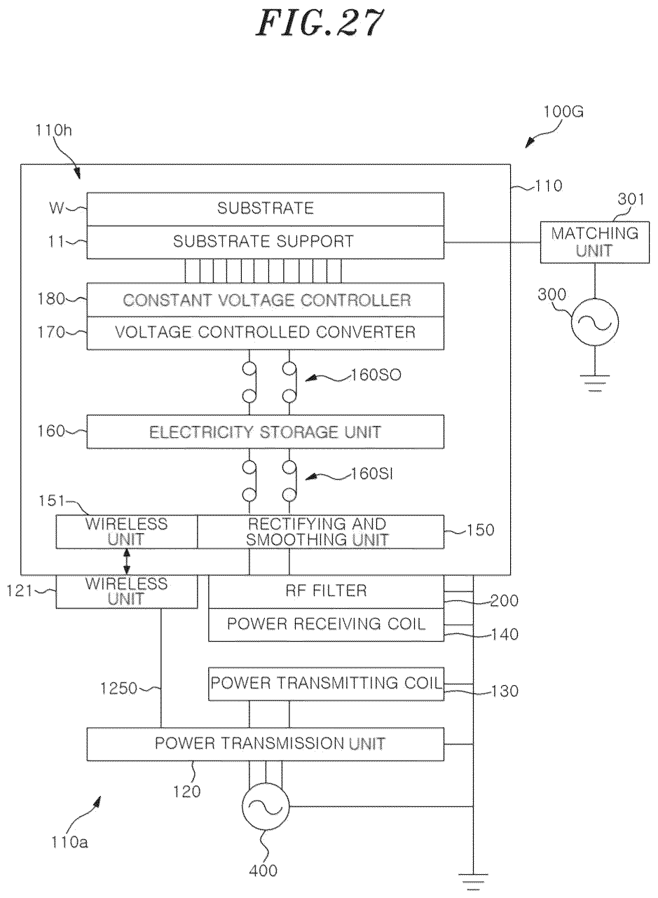

FIG. 27 is referred. FIG. 27 is a diagram schematically illustrating a plasma processing apparatus according to yet another exemplary embodiment. Hereinafter, a plasma processing apparatus 100G shown in FIG. 27 will be described from the viewpoint of differences from the plasma processing apparatus 100E shown in FIG. 7.

In the plasma processing apparatus 100G, the electricity storage unit 160 is not integrated with the voltage controlled converter 170 and the constant voltage controller 180. In addition, in the plasma processing apparatus 100G, the electricity storage unit 160 includes a pair of input switches 160SI and a pair of output switches 160SO. The electricity storage unit 160 is connected to the rectifying and smoothing unit 150 via the pair of input switches 160SI. The electricity storage unit 160 is connected to the voltage controlled converter 170 via the pair of output switches 160SO. Other configurations of the plasma processing apparatus 100G are similar to the corresponding configurations of the plasma processing apparatus 100E.

Hereinafter, a method for controlling a power storage amount of the electricity storage unit 160 in the plasma processing apparatus 100G will be described. The method for controlling the power storage amount includes a method for charging the electricity storage unit 160 when the electricity storage unit 160 is mounted on the plasma processing apparatus 100G. When the electricity storage unit 160 is mounted on the plasma processing apparatus 100G, the pair of input switches 160SI are set to an ON state (conductive state), thereby establishing connection of the electricity storage unit 160 to the rectifying and smoothing unit 150. Furthermore, the pair of output switches 160SO are set to the ON state (conductive state), thereby establishing connection of the electricity storage unit 160 to the voltage control converter 170.

Then, processing in an initial charging mode is performed. In the initial charging mode, charging of the electricity storage unit 160 is performed by wireless power feeding using the power transmission unit 120, the power transmitting coil unit 130, and the power receiving coil unit 140. In this connection, the power transmission unit 120 operates in the initial charging mode. When the voltage value of the electricity storage unit 160 detected by the voltage detector 155v reaches a predetermined value, the controller 152 of the rectifying and smoothing unit 150 transmits a signal indicating completion of charging to the power transmission unit 120 via the communication units 151 and 121. When the controller 122 of the power transmission unit 120 receives the signal indicating the completion of charging, the controller 122 transitions from the initial charging mode to a normal operation mode.

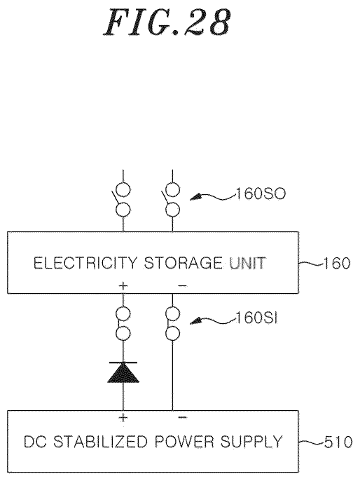

Hereinafter, FIG. 28 is referred. FIG. 28 is a diagram illustrating charging of an electricity storage unit of a plasma processing apparatus according to yet another exemplary embodiment. In a charging method according to another embodiment, the electricity storage unit 160 may be charged before being mounted on the plasma processing apparatus 100G, and then mounted on the plasma processing apparatus 100G.

Specifically, as shown in FIG. 28, before being mounted on the plasma processing apparatus 100G, the electricity storage unit 160 may be connected to a DC stabilized power supply 510 via the pair of input switches 160SI. The positive electrode of the electricity storage unit 160 may be connected to the positive output of the DC stabilized power supply 510 via one of the pair of input switches 160SI and a reverse current prevention diode. When charging the electricity storage unit 160, the pair of input switches 160SI are set to an ON state, and the pair of output switches 160SO are set to an OFF state (non-conductive state). After the charging of the electricity storage unit 160 is completed, the pair of input switches 160SI are set to the OFF state.

The charged electricity storage unit 160 is then mounted on the plasma processing apparatus 100G, connected to the rectifying and smoothing unit 150 via the pair of input switches 160SI, and connected to the voltage controlled converter 170 via the pair of output switches 160SO. Thereafter, the pair of input switches 160SI and the pair of output switches 160SO are set to an ON state.

The method for controlling the power storage amount of the electricity storage unit 160 may further include a method for discharging the electricity storage unit 160. In the method for discharging the electricity storage unit 160 of the plasma processing apparatus 100G, the pair of input switches 160SI and the pair of output switches 160SO are set to an OFF state (non-conductive state). Next, the electricity storage unit 160 is removed from the plasma processing apparatus 100G. Then, outside the plasma processing apparatus 100G, the power of the electricity storage unit 160 is discharged to a dummy load or the like connected to the electricity storage unit 160.

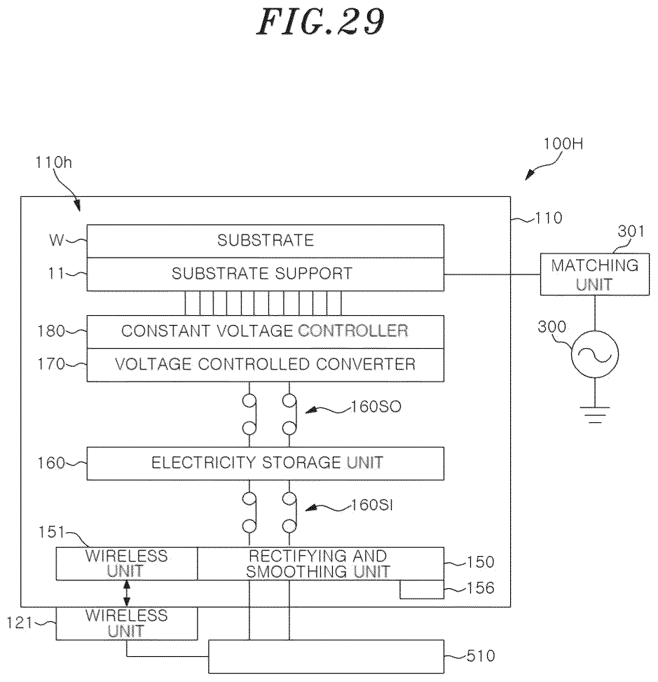

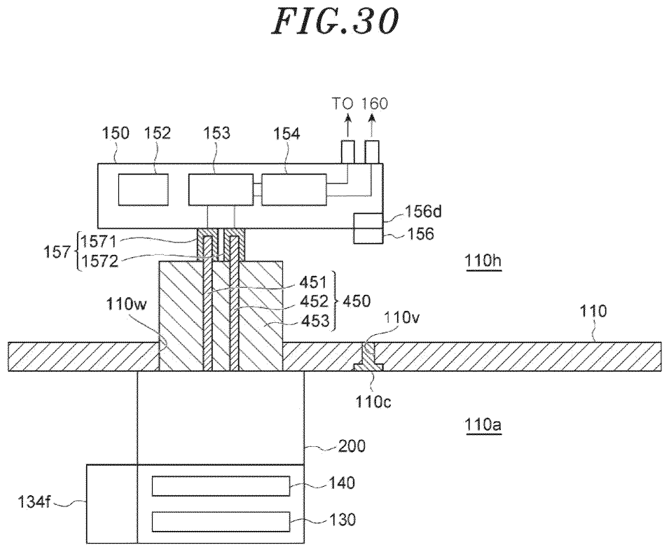

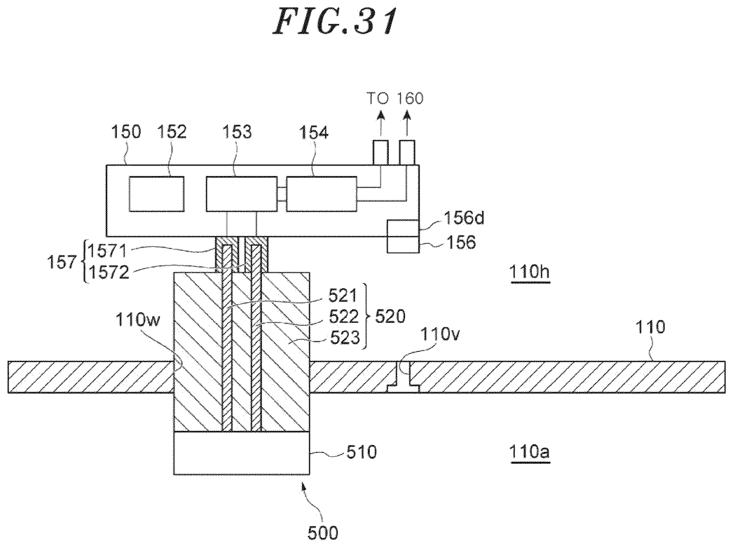

Hereinafter, FIGS. 29 to 31 are referred. FIG. 29 is a diagram schematically illustrating of a plasma processing apparatus according to yet another exemplary embodiment. FIG. 30 is a diagram illustrating a state in which a power receiving coil unit is connected to a rectifying and smoothing unit of the plasma processing apparatus shown in FIG. 29. FIG. 31 is a diagram illustrating a state in which a DC stabilized power supply is connected to the rectifying and smoothing unit of the plasma processing apparatus shown in FIG. 29. Hereinafter, a plasma processing apparatus 100H shown in FIG. 29 will be described from the viewpoint of differences from the plasma processing apparatus 100G shown in FIG. 27.

In the plasma processing apparatus 100H, the rectifying and smoothing unit 150 further includes a display 156, a driver 156d, and a power feeding input connector 157.

The power feeding input connector 157 is provided so as to be accessible from the outside of the ground frame 110. That is, the ground frame 110 is provided with an opening 110w for allowing access to the power feeding input connector 157 from the outside of the ground frame 110. The power feeding input connector 157 includes a first power feeding input terminal 1571 and a second power feeding input terminal 1572. In the examples of FIGS. 30 and 31, each of the first power feeding input terminal 1571 and the second power feeding input terminal 1572 is a female terminal, but may be a male terminal.

As described above, in the rectifying and smoothing unit 150, the rectifying circuit 153 includes a diode bridge. The rectifying circuit 153 is connected between the power feeding input connector 157 and the electricity storage unit 160. The rectifying circuit 153 is connected to the electricity storage unit 160 via the smoothing circuit 154.

As shown in FIG. 30, the plasma processing apparatus 100H further includes a power feeding output connector 450. The power feeding output connector 450 includes a first power feeding output terminal 451 and a second power feeding output terminal 452, and is detachable from the power feeding input connector 157. The first power feeding output terminal 451 and the second power feeding output terminal 452 are electrically connectable to the first power feeding input terminal 1571 and the second power feeding input terminal 1572. The first power feeding output terminal 451 and the second power feeding output terminal 452 are electrically connected to the first power feeding input terminal 1571 and the second power feeding input terminal 1572 through the opening 110w. To this end, the power feeding output connector 450 may further include an insulating member 453. The first power feeding output terminal 451 and the second power feeding output terminal 452 penetrate the insulating member 453 and protrude from the insulating member 453. When the first power feeding output terminal 451 and the second power feeding output terminal 452 are connected to the first power feeding input terminal 1571 and the second power feeding input terminal 1572, the insulating member 453 is interposed between each of the first power feeding output terminal 451 and the second power feeding output terminal 452 and the ground frame 110.

The power receiving coil unit 140 is disposed outside the ground frame 110, that is, in the space 110a, and is connected to the power feeding output connector 450. That is, the power receiving coil 141 is connected to the first power feeding output terminal 451 and the second power feeding output terminal 452. The RF filter 200 may be connected between the power receiving coil 141 and each of the first power feeding output terminal 451 and the second power feeding output terminal 452.

When the power receiving coil unit 140 is mounted on the plasma processing apparatus 100H, the power feeding output connector 450 is connected to the power feeding input connector 157. As a result, the power receiving coil unit 140 disposed outside the ground frame 110 is connected to electricity storage unit 160 via the power feeding output connector 450, the power feeding input connector 157, and the rectifying and smoothing unit 150. In addition, in the example shown in FIG. 30, the power receiving coil unit 140 is integrated with the power transmitting coil unit 130. The power receiving coil unit 140 and the power transmitting coil unit 130 are provided with a fan 134f for cooling the same. In addition, in the example shown in FIG. 30, the fan 134f is installed to the left of the power receiving coil unit 140 and the power transmitting coil unit 130, but the location at which the fan 134f is installed is not limited to the example shown in FIG. 30. The fan 134f may be installed to the right of or below the power receiving coil unit 140 and the power transmitting coil unit 130.

The ground frame 110 of the plasma processing apparatus 100H may further include an optical window 110v. The optical window 110v is interposed between the display 156 and the space outside the ground frame 110 so as to make the display 156 visible from the outside of the ground frame 110. The optical window 110v may be opened and closed by a metallic shielding member 110c. When the power receiving coil unit 140 is electrically connected to the rectifying and smoothing unit 150, the optical window 110v is closed by the shielding member 110c. When the optical window 110v is closed by the shielding member 110c, the shielding member 110c and the ground frame 110 are electrically connected.

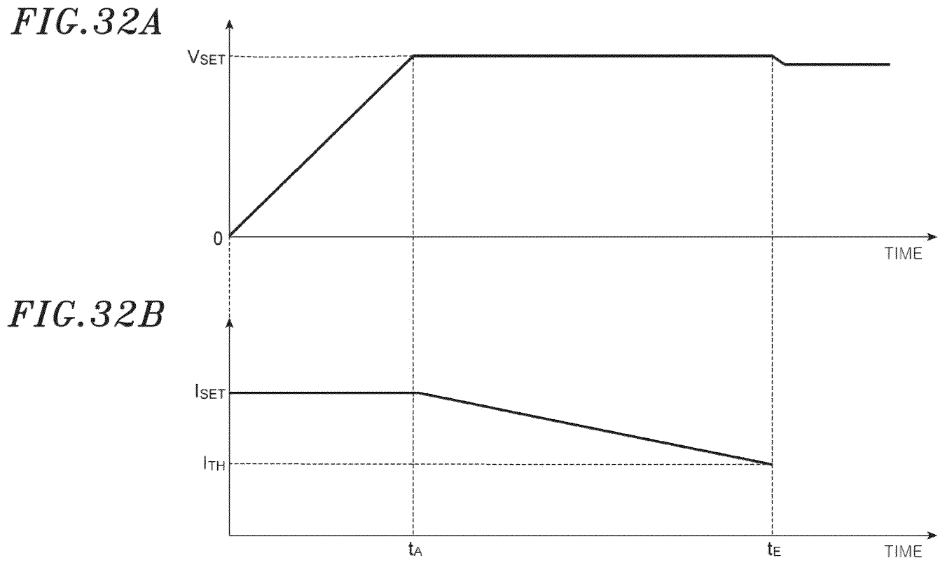

Hereinafter, the method for controlling the power storage amount of the electricity storage unit 160 of the plasma processing apparatus 100H will be described with reference to FIGS. 32A and 32B in addition to FIGS. 29 to 31. FIG. 32A is a timing chart showing an example of a voltage of the electricity storage unit, and FIG. 32B is a timing chart showing an example of a current supplied to the electricity storage unit. The method for controlling the power storage amount of the electricity storage unit 160 includes a method for charging the electricity storage unit 160.

In the method for charging the electricity storage unit 160 of the plasma processing apparatus 100H, the power feeding output connector 450 is removed from the power feeding input connector 157, and the power receiving coil unit 140 is removed from the plasma processing apparatus 100H.

In addition, in the method for charging the electricity storage unit 160 of the plasma processing apparatus 100H, a power supply unit 500 is used to charge the electricity storage unit 160, as shown in FIG. 31. The power supply unit 500 includes the DC stabilized power supply 510 and a power feeding connector 520. The power feeding connector 520 includes a first power feeding terminal 521 and a second power feeding terminal 522, and is detachable from the power feeding input connector 157. The first power feeding terminal 521 and the second power feeding terminal 522 are connected to the DC stabilized power supply 510 disposed outside the ground frame 110, that is, in the space 110a. The first power feeding terminal 521 and the second power feeding terminal 522 are electrically connectable to the first power feeding input terminal 1571 and the second power feeding input terminal 1572.

In the method for charging the electricity storage unit 160 of the plasma processing apparatus 100H, the first power feeding terminal 521 and the second power feeding terminal 522 are connected to the first power feeding input terminal 1571 and the second power feeding input terminal 1572 as shown in FIG. 31. The first power feeding terminal 521 and the second power feeding terminal 522 are electrically connected to the first power feeding input terminal 1571 and the second power feeding input terminal 1572 through the opening 110w. To this end, the power feeding connector 520 may further include an insulating member 523. The first power feeding terminal 521 and the second power feeding terminal 522 penetrate the insulating member 523 and protrude from the insulating member 523. When the first power feeding terminal 521 and the second power feeding terminal 522 are connected to the first power feeding input terminal 1571 and the second power feeding input terminal 1572, the insulating member 523 is interposed between each of the first power feeding terminal 521 and the second power feeding terminal 522 and the ground frame 110.

Next, in the method for charging the electricity storage unit 160 of the plasma processing apparatus 100H, power is fed from the DC stabilized power supply 510 to the electricity storage unit 160, and the electricity storage unit 160 is charged. In addition, the initial set value of the current supplied from the DC stabilized power supply 510 to the electricity storage unit 160 is the current value I_{SET} shown in FIG. 32B.

The charging state of the electricity storage unit 160 is monitored by the controller 152. When the electricity storage unit 160 is being charged, the voltage value of the electricity storage unit 160 may be monitored by the controller 152 using the voltage detector 155v. Furthermore, when the electricity storage unit 160 is being charged, the value of the current flowing from the DC stabilized power supply 510 to the electricity storage unit 160 (that is, the current value) may be monitored by the controller 152 using the current detector 155i.

As shown in FIGS. 32A and 32B, the controller 152 may monitor the voltage value of the electricity storage unit 160, and complete (that is, stop) the charging of the electricity storage unit 160 at a time ta when the voltage value of the electricity storage unit 160 reaches a set voltage value V_{SET}, or after a time TA and before a time t_{E} described later. Alternatively, the controller 152 may monitor the voltage value of the electricity storage unit 160 and the current value from the DC stabilized power supply 510 to the electricity storage unit 160, and complete (that is, stop) charging of the electricity storage unit 160 at the time t_{E} when the current value reaches a threshold value I_{TH} after the time t_{A} when the voltage value of the electricity storage unit 160 reaches the set voltage value V_{SET}. The threshold I_{TH} is set to, for example, a value needed for the controller 152 to activate. The threshold I_{TH} may be set to, for example, 0.5 A. The controller 152 may transmit a signal to the DC stabilized power supply 510 to stop feeding power from the DC stabilized power supply 510 through communication via the communication units 121 and 151, thereby stopping charging of the electricity storage unit 160.

The controller 152 may cause the display 156 to display the charging state of the electricity storage unit 160. The display 156 may include a semiconductor light emitting device (that is, an LED). The controller 152 may control the driver 156d to cause the display 156 to display the charging state of the electricity storage unit 160. In this connection, the optical window 110v is opened so that the display 156 may be visible from the outside of the ground frame 110.

The display 156 may indicate whether charging of the electricity storage unit 160 is complete by turning on or off an LED. Alternatively, the display 156 may indicate the charging state of the electricity storage unit 160 by the emission light color of the LED. For example, the display 156 may indicate that the voltage value of the electricity storage unit 160 is a voltage value at which the rectifying and smoothing unit 150 may operate by emitting green light. Furthermore, the display 156 may emit orange light to indicate that the voltage value of the electricity storage unit 160 is a voltage value at which the rectifying and smoothing unit 150 may operate, but there is still room for charging. Furthermore, the display 156 may emit red light to indicate that the voltage value of the electricity storage unit 160 is a voltage value at which the rectifying and smoothing unit 150 may not operate and charging is needed. Alternatively, the display 156 may include a seven-segment LED, and a numerical value representing the voltage value of the electricity storage unit 160 may be displayed by the seven-segment LED. When the display 156 is used, the charging of the electricity storage unit 160 may be stopped manually by an operator when the charging is completed.

In the plasma processing apparatus 100H, the first power feeding input terminal 1571 and the second power feeding input terminal 1572 are connected to the electricity storage unit 160 via the diode bridge of the rectifying circuit 153 of the rectifying and smoothing unit 150. Accordingly, in order to charge the electricity storage unit 160, it is possible to electrically connect the DC stabilized power supply 510 to the electricity storage unit 160 without using a reverse current prevention circuit. Furthermore, when the power receiving coil unit 140 is electrically connected to the rectifying and smoothing unit 150 after charging of the electricity storage unit 160 is completed (see FIG. 30), the first power feeding input terminal 1571 and the second power feeding input terminal 1572 are not charged. Therefore, the operator is prevented from getting an electric shock.

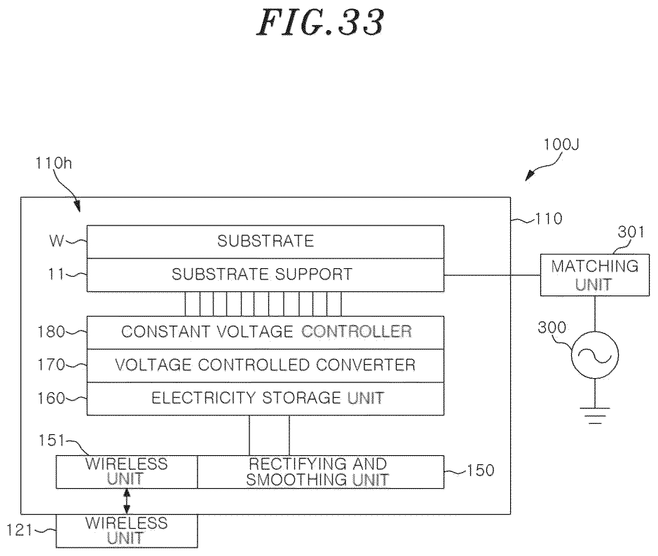

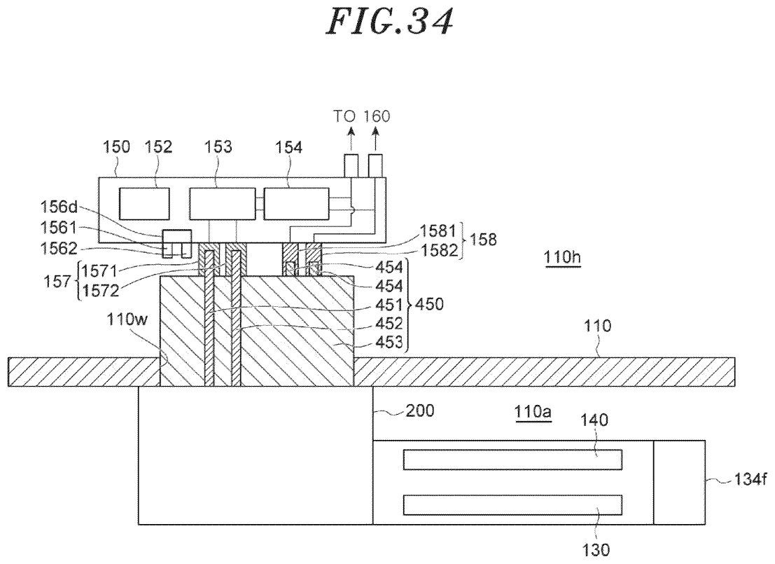

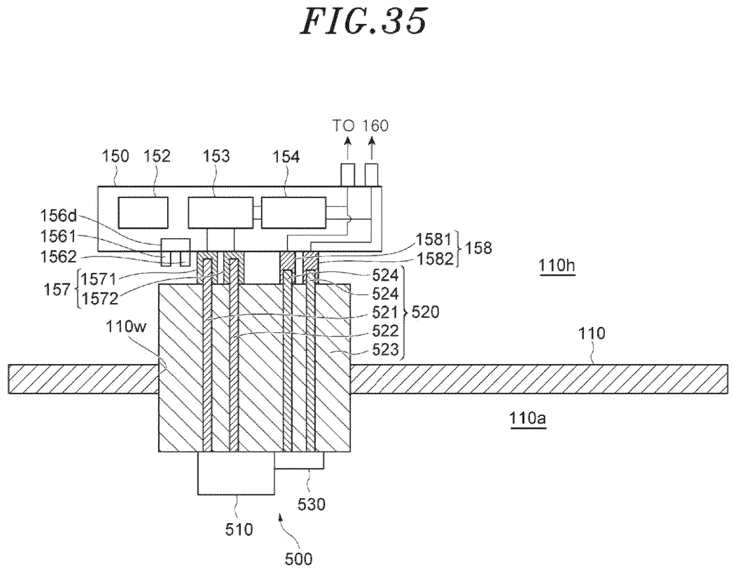

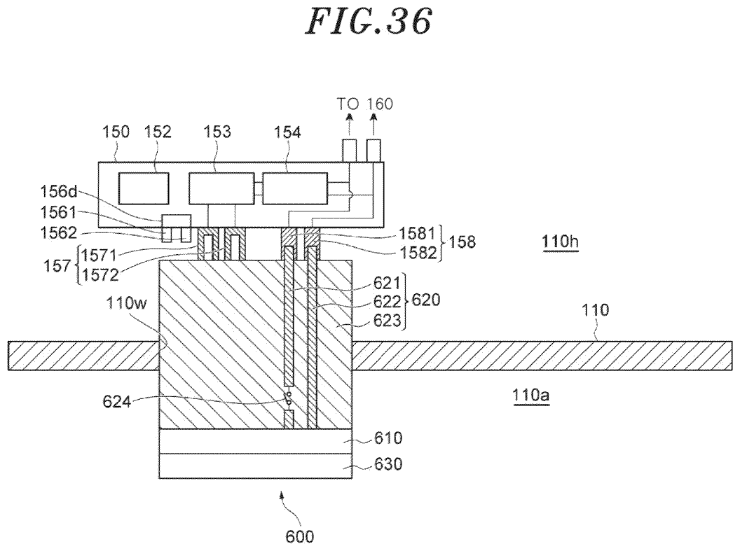

Hereinafter, FIGS. 33 to 36 are referred. FIG. 33 is a diagram schematically illustrating a plasma processing apparatus according to yet another exemplary embodiment. FIG. 34 is a diagram illustrating a state in which a power receiving coil unit is connected to a rectifying and smoothing unit of a plasma processing apparatus according to yet another exemplary embodiment. FIG. 35 is a diagram illustrating a state in which a DC stabilized power supply is connected to a rectifying and smoothing unit of a plasma processing apparatus according to yet another exemplary embodiment. FIG. 36 is a diagram illustrating a state in which a discharge unit is connected to a rectifying and smoothing unit of a plasma processing apparatus according to yet another exemplary embodiment. Hereinafter, a plasma processing apparatus 100J shown in FIG. 33 will be described from the viewpoint of differences from the plasma processing apparatus 100H shown in FIG. 33.

As shown in FIG. 34, in the plasma processing apparatus 100J, the rectifying and smoothing unit 150 includes the driver 156d and the power feeding input connector 157, similar to the rectifying and smoothing unit 150 of the plasma processing apparatus 100H. As shown in FIG. 34, the plasma processing apparatus 100J includes the power feeding output connector 450, similar to the plasma processing apparatus 100H. In the plasma processing apparatus 100J, the rectifying and smoothing unit 150 further includes a display 1561, a display 1562, and a discharge output connector 158.

As in the case of the plasma processing apparatus 100H, when the power receiving coil unit 140 is mounted on the plasma processing apparatus 100J, the power feeding output connector 450 is connected to the power feeding input connector 157. As a result, the power receiving coil unit 140 disposed outside the ground frame 110 is connected to the electricity storage unit 160 via the power feeding output connector 450, the power feeding input connector 157, and the rectifying and smoothing unit 150. In addition, in the example shown in FIG. 34, the power receiving coil unit 140 is integrated with the power transmitting coil unit 130. The power receiving coil unit 140 and the power transmitting coil unit 130 are provided with the fan 134f for cooling the same. In addition, in the example shown in FIG. 34, the fan 134f is installed to the right of the power receiving coil unit 140 and the power transmitting coil unit 130, but the location at which the fan 134f is installed is not limited to the example shown in FIG. 34. The fan 134 f may be installed above or below the power receiving coil unit 140 and the power transmitting coil unit 130.

In the plasma processing apparatus 100J, the power feeding output connector 450 may further include an insulating portion 454. The insulating portion 454 is made of an insulating material. The insulating portion 454 may be a pair of insulating pins that are inserted into the first discharge output terminal 1581 and the second discharge output terminal 1582, respectively, when each of the first discharge output terminal 1581 and the second discharge output terminal 1582 is a female terminal. Alternatively, the insulating portion 454 may be an insulating cap that covers the first discharge output terminal 1581 and the second discharge output terminal 1582.

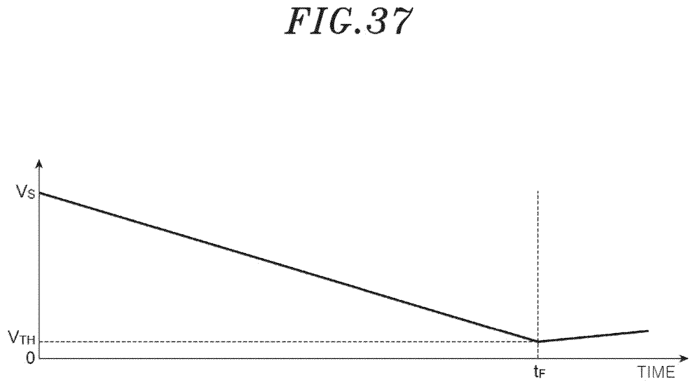

Hereinafter, the method for controlling the power storage amount of the electricity storage unit 160 of the plasma processing apparatus 100J will be described with reference to FIGS. 32A, 32B and 37, in addition to FIGS. 33 to 36. FIG. 37 is a timing chart of an example of the voltage of the electricity storage unit.

The method for controlling the power storage amount of the electricity storage unit 160 of the plasma processing apparatus 100J includes a method for charging the electricity storage unit 160. In the method for charging the electricity storage unit 160 of the plasma processing apparatus 100J, the power feeding output connector 450 is removed from the power feeding input connector 157, and the power receiving coil unit 140 is removed from the plasma processing apparatus 100H.

In addition, in the method for charging the electricity storage unit 160 of the plasma processing apparatus 100J, the power supply unit 500 is used as shown in FIG. 35. The power supply unit 500 includes the DC stabilized power supply 510 and the power feeding connector 520, as described above in relation to charging of the electricity storage unit 160 of the plasma processing apparatus 100H.

In the method for charging the electricity storage unit 160 of the plasma processing apparatus 100J, as shown in FIG. 35, the first power feeding terminal 521 and the second power feeding terminal 522 are connected to the first power feeding input terminal 1571 and the second power feeding input terminal 1572. The first power feeding terminal 521 and the second power feeding terminal 522 are electrically connected to the first power feeding input terminal 1571 and the second power feeding input terminal 1572 through the opening 110w.

Next, in the method for charging the electricity storage unit 160 of the plasma processing apparatus 100J, power is fed from the DC stabilized power supply 510 to the electricity storage unit 160, and the electricity storage unit 160 is charged.

The charging state of the electricity storage unit 160 is monitored by the controller 152. When the electricity storage unit 160 is being charged, the voltage value of the electricity storage unit 160 may be monitored by the controller 152 using the voltage detector 155v. Furthermore, when the electricity storage unit 160 is being charged, the value of the current flowing from the DC stabilized power supply 510 to the electricity storage unit 160 (that is, the current value) may be monitored by the controller 152 using the current detector 155i.

As shown in FIGS. 32A and 32B, the controller 152 may monitor the voltage value of the electricity storage unit 160, and complete (that is, stop) the charging of the electricity storage unit 160 at the time t_{A} when the voltage value of the electricity storage unit 160 reaches the set voltage value V_{SET}, or after the time T_{A} and before the time t_{E} described later. Alternatively, the controller 152 may monitor the voltage value of the electricity storage unit 160 and the current value from the DC stabilized power supply 510 to the electricity storage unit 160, and complete (that is, stop) charging of the electricity storage unit 160 at the time t_{E} when the current value reaches the threshold value I_{TH} after the time t_{A} when the voltage value of the electricity storage unit 160 reaches the set voltage value V_{SET}. The controller 152 may transmit a signal to the DC stabilized power supply 510 to stop feeding power from the DC stabilized power supply 510 through communication via the communication units 121 and 151, thereby stopping charging of the electricity storage unit 160.

The controller 152 may cause the display 1561 to display the charging state of the electricity storage unit 160. The display 1561 may include a semiconductor light emitting device (that is, an LED) similar to the display 156 in the plasma processing apparatus 100H. The controller 152 may control the driver 156d to cause the display 1561 to display the charging state of the electricity storage unit 160. In addition, in this connection, the insulating member 523 may be formed from an optically transparent material so that the display 1561 may be visible from the outside of the ground frame 110. The display of the charging state of the electricity storage unit 160 on the display 1561 may be similar to the display on the display 156 in the plasma processing apparatus 100H.

In one embodiment, the power supply unit 500 may further include a tester 530. The power feeding connector 520 may also include a pair of tester terminals 524. The pair of tester terminals 524 may be connected to the first discharge output terminal 1581 and the second discharge output terminal 1582, and may also be disconnected from the first discharge output terminal 1581 and the second discharge output terminal 1582. The pair of tester terminals 524 are connected to the first discharge output terminal 1581 and the second discharge output terminal 1582 when the first power feeding terminal 521 and the second power feeding terminal 522 are connected to the first power feeding input terminal 1571 and the second power feeding input terminal 1572. When the first power feeding terminal 521 and the second power feeding terminal 522 are separated from the first power feeding input terminal 1571 and the second power feeding input terminal 1572, the pair of tester terminals 524 are separated from the first discharge output terminal 1581 and the second discharge output terminal 1582.

In a state in which the pair of tester terminals 524 are connected to the first discharge output terminal 1581 and the second discharge output terminal 1582, the tester 530 monitors the voltage value of the electricity storage unit 160. Accordingly, when charging the electricity storage unit 160 from the DC stabilized power supply 510, the charging state of the electricity storage unit 160 may be monitored by the tester 530.

In the plasma processing apparatus 100J, the first power feeding input terminal 1571 and the second power feeding input terminal 1572 are connected to the electricity storage unit 160 via the diode bridge of the rectifying circuit 153 of the rectifying and smoothing unit 150. Accordingly, in order to charge the electricity storage unit 160, it is possible to electrically connect the DC stabilized power supply 510 to the electricity storage unit 160 without using a reverse current prevention circuit. Furthermore, when the power receiving coil unit 140 is electrically connected to the rectifying and smoothing unit 150 after charging of the electricity storage unit 160 is completed (see FIG. 34), the first power feeding input terminal 1571 and the second power feeding input terminal 1572 are not charged. Therefore, the operator is prevented from getting an electric shock.

The method for controlling the power storage amount of the electricity storage unit 160 of the plasma processing apparatus 100J includes a method for discharging the electricity storage unit 160. In the method for discharging the electricity storage unit 160 of the plasma processing apparatus 100J, the power feeding output connector 450 is removed from the power feeding input connector 157, and the power receiving coil unit 140 is removed from the plasma processing apparatus 100H.

In addition, in the method for discharging the electricity storage unit 160 of the plasma processing apparatus 100J, a discharge unit 600 is used as shown in FIG. 36. The discharge unit 600 includes a discharge load 610 and a discharge connector 620. The discharge unit 600 may further include a fan 630. The fan 630 is provided to cool the discharge load 610.

The discharge connector 620 includes a first discharge terminal 621 and a second discharge terminal 622, and is detachable from the discharge output connector 158. The first discharge terminal 621 and the second discharge terminal 622 are connected to the discharge load 610 that is disposed outside the ground frame 110, that is, in the space 110a. The first discharge terminal 621 and the second discharge terminal 622 are electrically connectable to the first discharge output terminal 1581 and the second discharge output terminal 1582. The first discharge terminal 621 may be connected to the discharge load 610 via a switch 624.

In the method for discharging the electricity storage unit 160 of the plasma processing apparatus 100J, as shown in FIG. 36, the first discharge terminal 621 and the second discharge terminal 622 are connected to the first discharge output terminal 1581 and the second discharge output terminal 1582 with the switch 624 set to an OFF state (that is, non-conductive state). The first discharge terminal 621 and the second discharge terminal 622 are electrically connected to the first discharge output terminal 1581 and the second discharge output terminal 1582 through the opening 110w. To this end, the discharge connector 620 may further include an insulating member 623. The first discharge terminal 621 and the second discharge terminal 622 penetrate the insulating member 623 and protrude from the insulating member 623. When the first discharge terminal 621 and the second discharge terminal 622 are connected to the first discharge output terminal 1581 and the second discharge output terminal 1582, the insulating member 623 is interposed between each of the first discharge terminal 621 and the second discharge terminal 622 and the ground frame 110.

Next, in the method for discharging the electricity storage unit 160, the switch 624 is set to an ON state (that is, the conductive state). As a result, the power of the electricity storage unit 160 is discharged to the discharge load 610.

As shown in FIG. 37, while the electricity storage unit 160 is discharging, the voltage value of the electricity storage unit 160 decreases from a voltage value V_{S} at the start of discharge of the electricity storage unit 160. The discharge of the electricity storage unit 160 is completed and stopped at a time t_{F} when the voltage value of the electricity storage unit 160 reaches a threshold value V_{TH}. The threshold value V_{TH} is set, for example, to a value that does not activate the controller 152 and that does not affect the human body. The threshold value V_{TH} may be set to, for example, 2.5V. After the discharge of the electricity storage unit 160 is completed, the switch 624 is set to an OFF state, and the discharge unit 600 is removed from the plasma processing apparatus 100J.

The controller 152 may cause the display 1562 to display the discharge state of the electricity storage unit 160. The display 1562 may include a semiconductor light emitting device (that is, an LED). The controller 152 may control the driver 156d to cause the display 1562 to display the discharge state of the electricity storage unit 160. In this connection, the insulating member 523 may be formed from an optically transparent material so that the display 1562 may be visible from the outside of the ground frame 110. In addition, the display 1562 may be configured to be inoperable and turned off when the discharge of the electricity storage unit 160 is completed. In addition, the plasma processing apparatus 100J may have, instead of the display 1561 and the display 1562, a single display that may be used in the same manner as both the display 1561 and the display 1562.

According to the plasma processing apparatus 100J, the electricity storage unit 160 may be discharged to the discharge load 610 disposed outside the ground frame 110 while the electricity storage unit 160 is mounted on the plasma processing apparatus 100J. Accordingly, an operator who is working to discharge the electricity storage unit 160 is prevented from getting an electric shock.

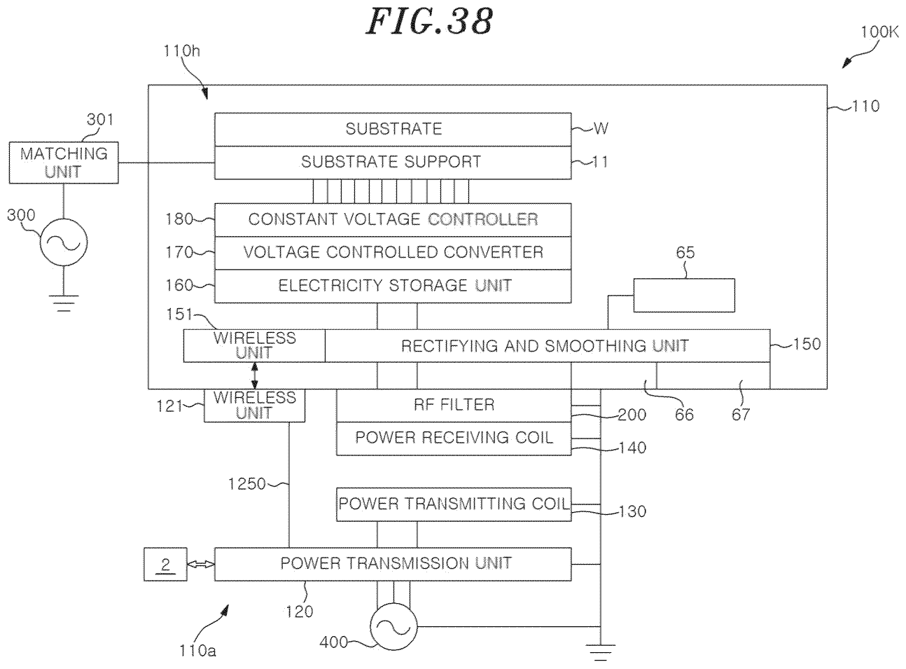

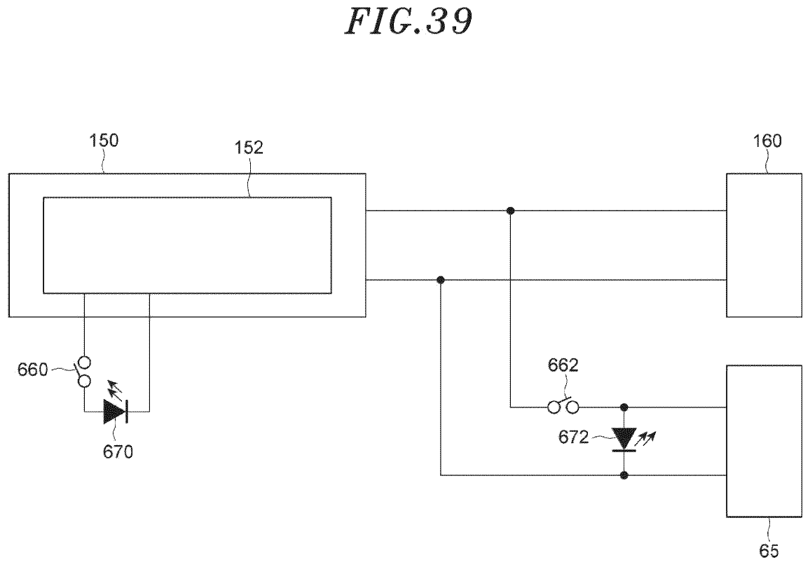

Hereinafter, FIGS. 38 and 39 are referred. FIG. 38 is diagram schematically illustrating a plasma processing apparatus according to yet another exemplary embodiment. FIG. 39 is a diagram illustrating a configuration related to the discharge of the electricity storage unit in a plasma processing apparatus according to yet another exemplary embodiment. Hereinafter, the plasma processing apparatus 100K shown in FIG. 38 will be described from the viewpoint of differences from the plasma processing apparatus 100E shown in FIG. 7.

As shown in FIG. 38, the plasma processing apparatus 100K further includes a discharge load 65, a plurality of switches 66, and a display 67. The discharge load 65 is a load provided solely for discharging the electricity storage unit 160, that is, a discharge-only load, or at least one of the aforementioned plurality of power consuming members 240 (for example, at least one heater). The discharge load 65 is disposed at a distance equal to or greater than the insulation distance from the ground frame 110. The plurality of switches 66 may be provided in the non-reduced pressure space of the space 110h so as to be accessible from the outside of the ground frame 110. The display 67 may also be provided so as to be visible from the outside of the ground frame 110.

As shown in FIG. 39, one end of the discharge load 65 is connected to one (for example, the positive line 160p) of a pair of power feeding lines connecting the rectifying and smoothing unit 150 and the electricity storage unit 160 to each other. The other end of the discharge load 65 is connected to the other of the pair of power feeding lines (for example, the negative line 160m).

The plurality of switches 66 includes a discharge mode switch 660 and a switch 662 (or a direct mode switch). In addition, the display 67 includes a display portion 670 and a display portion 672. Each of the display portion 670 and the display portion 672 is a discharge state display portion configured to indicate the discharge state of the electricity storage unit 160, and may be an LED.

The discharge mode switch 660 and the display portion 670 are connected in series to the controller 152. In addition, the switch 662 is connected between the discharge load 65 and one (for example, the positive line 160p) of the pair of power feeding lines connecting the rectifying and smoothing unit 150 and the electricity storage unit 160 to each other. The display portion 672 is connected in parallel to the discharge load 65 with respect to the electricity storage unit 160.

In the embodiment shown in FIG. 39, the discharge mode switch 660 may be set to an ON state as a hardware interlock when an abnormality occurs in the plasma processing apparatus 100K. Alternatively, the discharge mode switch 660 may be manually set to the ON state by an operator in order to discharge the electricity storage unit 160. When the discharge mode switch 660 is set to the ON state, the switch 662 may be set to the ON state manually by an operator, or may be set to the ON state under the control of the controller 2 or 152. When the discharge of the electricity storage unit 160 is completed, the discharge mode switch 660 and the switch 662 may be set to an OFF state manually by an operator, or may be set to the OFF state under the control of the controller 2 or 152. In addition, the switch 662 may be used in common with the discharge mode switch 660.

In the embodiment shown in FIG. 39, the method for controlling the power storage amount of the electricity storage unit 160 of the plasma processing apparatus 100K includes a method for discharging the electricity storage unit 160. The discharge of the electricity storage unit 160 starts when the discharge mode switch 660 and the switch 662 are set to an ON state. When the discharge mode switch 660 and the switch 662 are set to the ON state, the power of the electricity storage unit 160 is discharged to the discharge load 65.

While the electricity storage unit 160 is discharging, the voltage value of the electricity storage unit 160 decreases from the voltage value V_{S} at the start of discharge of the electricity storage unit 160 (see FIG. 37). The discharge of the electricity storage unit 160 is completed and stopped at the time t_{F} when the voltage value of the electricity storage unit 160 reaches the threshold value V_{TH}. After the discharge of the electricity storage unit 160 is completed, the discharge mode switch 660 and the switch 662 are set to an OFF state.

Similar to the aforementioned display 1562, the display portions 670 and 672 perform display (for example, by emitting light from an LED) to indicate the discharge state of the electricity storage unit 160 while the electricity storage unit 160 is discharging. The display portions 670 and 672 may be configured to be unable to operate and turn off when the discharge of the electricity storage unit 160 is completed.

In the embodiment shown in FIG. 39, the power of the electricity storage unit 160 is discharged to the discharge load 65, but the power of the electricity storage unit 160 may be discharged to a load other than the discharge load 65. For example, the power of the electricity storage unit 160 may be discharged to at least one of the plurality of power consuming members 240.

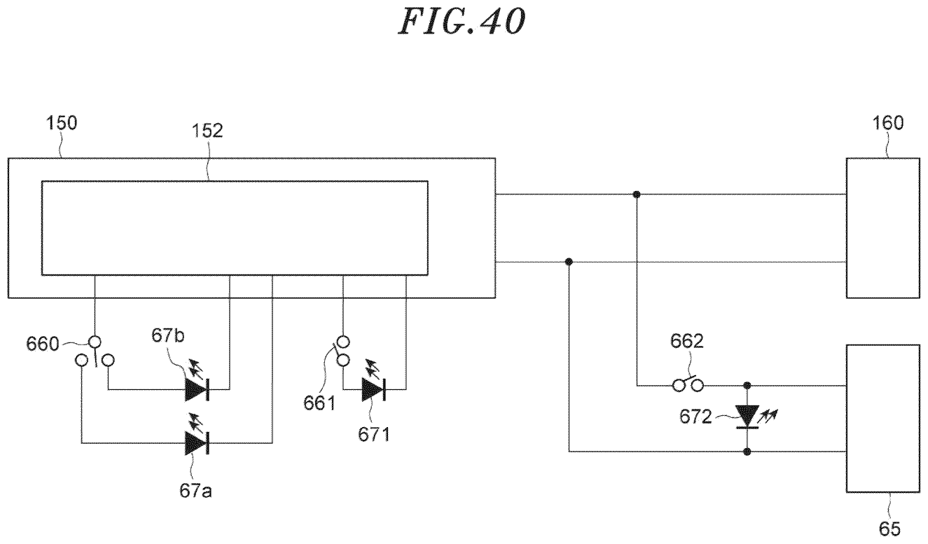

Hereinafter, FIG. 40 is referred. FIG. 40 is a diagram illustrating a configuration related to the discharge of the electricity storage unit in a plasma processing apparatus according to yet another exemplary embodiment. The configuration related to the discharge of the electricity storage unit 160 shown in FIG. 40 may be employed in the plasma processing apparatus 100K. Hereinafter, the embodiment of FIG. 40 will be described from the viewpoint of the differences from the embodiment of FIG. 39.

In the embodiment of FIG. 40, the discharge load 65 may be a discharge-only load. In the embodiment of FIG. 40, the plurality of switches 66 includes the discharge mode switch 660, a switch 661 (a primary discharge mode switch), and a switch 662 (a direct mode switch or a secondary discharge mode switch). In addition, the display 67 includes a display unit 67a (direct discharge mode display portion), a display portion 67b (a two-stage discharge mode display portion), a display unit 671 (primary discharge state display portion), and a display portion 672 (direct mode discharge state display portion or secondary discharge state display portion). Each of the display portions 67a, 67b, 671, and 672 may be an LED.

The discharge mode switch 660 is connected to the controller 152. The display portions 67a and 67b are connected in parallel between the discharge mode switch 660 and the controller 152. The switch 661 and the display portion 671 are connected in series to the controller 152. In addition, the switch 662 is connected between the discharge load 65 and one (for example, the positive line 160p) of the pair of power feeding lines connecting the rectifying and smoothing unit 150 and the electricity storage unit 160 to each other. The display portion 672 is connected in parallel to the discharge load 65 with respect to the electricity storage unit 160.

In the embodiment shown in FIG. 40, the discharge mode switch 660 may be set to an ON state as a hardware interlock when an abnormality occurs in the plasma processing apparatus 100K. Alternatively, the discharge mode switch 660 may be manually set to the ON state by an operator in order to discharge the electricity storage unit 160.

When the discharge mode switch 660 is set to an ON state, the discharge mode switch 660 is selectively connected to one of the display portions 67a and 67b. When the discharge mode switch 660 is connected to the display portion 67a, the switch 662 is set to the ON state, and the electricity storage unit 160 is discharged using only the discharge load 65 (that is, direct mode discharge) as in the embodiment of FIG. 39. In this connection, the display portion 67a displays (for example, by emitting light from an LED) that direct mode discharge is being performed. Furthermore, the display portion 672 displays (for example, by emitting light from an LED) that direct mode discharge is being performed.

When the discharge mode switch 660 is connected to the display portion 67b, the discharge is performed in a two-stage discharge mode. In this connection, the display portion 67b displays (for example, by emitting light from an LED) that the discharge is being performed in the two-stage discharge mode. In the discharge in the two-stage discharge mode, in the first stage, the switch 661 is set to an ON state and the power of the electricity storage unit 160 is discharged to at least one of the plurality of power consuming members 240 described above (for example, at least one heater). In this connection, the display portion 671 displays (for example, by emitting light from an LED) an indication that the first stage of discharging is being performed.

In the discharge in the two-stage discharge mode, in the second stage, the switch 661 is set to an OFF state and the switch 662 is set to an ON state, and the power of the electricity storage unit 160 is discharged to the discharge load 65. In this connection, the display portion 672 displays (for example, by emitting light from an LED) that the second stage of discharge is being performed.

In the embodiment of FIG. 40, the states of each of the discharge mode switch 660, the switch 661, and the switch 662 may be switched manually by an operator, or may be switched under the control of the controller 2 or 152. In addition, the switch 661 may also be used for switching the discharge mode switch 660 to the two-stage discharge mode. In addition, the switch 662 may be used in common with the discharge mode switch 660 for switching to the direct discharge mode.

That is, the discharge mode switch 660 may also function as at least one of the switches 661 and 662.

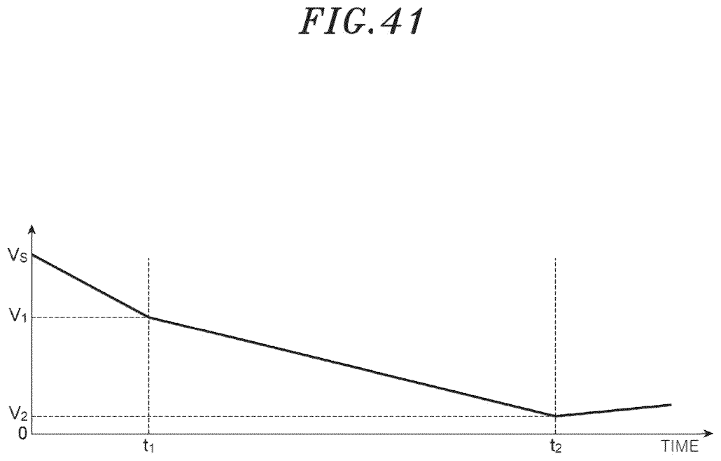

In the embodiment shown in FIG. 40, the method for controlling the power storage amount of the electricity storage unit 160 of the plasma processing apparatus 100K includes a method for discharging the electricity storage unit 160. As described above, the discharge of the electricity storage unit 160 includes the direct mode discharge and the two-stage discharge mode. Hereinafter, the method for discharging electricity storage unit 160 in the two-stage discharge mode will be described with reference to FIG. 41. FIG. 41 is a timing chart of an example of the voltage of the electricity storage unit.

The discharging method in the two-stage discharge mode is started when the discharge mode switch 660 is switched to select the two-stage discharge mode (connection to the display portion 67b) and when the switch 661 is set to an ON state. Then, the first stage of discharge is performed. In the first stage of discharge, the power of the electricity storage unit 160 is discharged to at least one of the plurality of power consuming members 240 (for example, at least one heater).

While the electricity storage unit 160 is discharging, the voltage value of the electricity storage unit 160 decreases from the voltage value Vs at the start of discharge of the electricity storage unit 160, as shown in FIG. 41. The first stage of discharge of the electricity storage unit 160 is completed and stopped at a time t₁ when the voltage value of the electricity storage unit 160 reaches a threshold value V₁. The threshold value V₁ is set to, for example, a value at which the charge of the electricity storage unit 160 may not be discharged to the power consuming member 240. The threshold V₁ may be set, for example, to an input lower limit voltage value of the voltage controlled converter.

Next, the switch 661 is set to an OFF state, and switch 662 is set to an ON state. Then, the second stage of discharge is performed. In the second stage of discharge, the power of electricity storage unit 160 is discharged to the discharge load 65.

During the second stage of discharge of the electricity storage unit 160, the voltage value of the electricity storage unit 160 further decreases as shown in FIG. 41. The second stage of discharge of the electricity storage unit 160 is completed and stopped at a time t₂ when the voltage value of the electricity storage unit 160 reaches a threshold value V₂. After the second stage of discharge of the electricity storage unit 160 is completed, the discharge mode switch 660 and the switch 662 are set to an OFF state. The threshold value V₂ is set, for example, to a value that does not activate the controller 152 and that does not affect the human body. The threshold VTH may be set to, for example, 2.5V.

In the embodiment shown in FIGS. 40 and 41, the power of the electricity storage unit 160 is discharged to at least one of the plurality of power consuming members 240 in the first stage of discharge, and is discharged to the discharge load 65 in the second stage of discharge, but the discharge of the power of the electricity storage unit 160 is not limited to this example. The power of the electricity storage unit 160 may be discharged to the discharge load 65 in the first stage of discharge, and may be discharged to at least one of the plurality of power consuming members 240 in the second stage of discharge. Furthermore, the power of the electricity storage unit 160 may be simultaneously discharged to at least one of the plurality of power consuming members 240 and the discharge load 65 only during a specific period of time.

As described above, when the first stage discharge is being performed, the display portion 671 performs a display (for example, by emitting light from an LED) to indicate that the first stage discharge is being performed. The display portion 671 may be turned off at the time t₁. Furthermore, when the second-stage discharge is being performed, the display portion 672 performs a display (for example, by emitting light from an LED) to indicate that the second-stage discharge is being performed. The display portion 672 may be turned off at the time t₂.

Although various exemplary embodiments have been described above, various additions, omissions, substitutions, and modifications may be made without being limited to the above-described exemplary embodiments. In addition, elements from different embodiments may be combined to form other embodiments. Herein, various exemplary embodiments included in the present disclosure are described in [E1] to [E14] below.

### E1

A plasma processing apparatus comprising:
a plasma processing chamber;
a substrate support disposed within the plasma processing chamber;
a high frequency power supply configured to generate high frequency power;
an electrode or an antenna electrically connected to the high frequency power supply to receive the high frequency power for generating a plasma from a gas within the plasma processing chamber;
a power consuming member disposed within the plasma processing chamber or the substrate support;
a ground frame that is grounded and surrounds the substrate support together with the plasma processing chamber;
an electricity storage unit disposed within a space surrounded by the ground frame and electrically connected to the power consuming member;
a rectifying and smoothing unit disposed within the space surrounded by the ground frame, including:
   a power feeding input connector comprising a first power feeding input terminal and a second power feeding input terminal and provided so as to be accessible from an outside of the ground frame, and
   a rectifying circuit comprising a diode bridge and connected between the power feeding input connector and the electricity storage unit;
a power feeding output connector comprising a first feeding output terminal and a second power feeding output terminal which are electrically connectable to the first power feeding input terminal and the second power feeding input terminal, the power feeding output connector being detachable from the power feeding input connector; and
a power receiving coil disposed outside the ground frame, electrically connected to the power feeding output connector, and capable of receiving power from a power transmitting coil by electromagnetic induction coupling.

### E2

The plasma processing apparatus of E1, wherein:
the rectifying and smoothing unit further comprises a discharge output connector that is accessible from the outside of the ground frame; and
the discharge output connector comprises a first discharge output terminal and a second discharge output terminal that are respectively connected to two power feeding lines that connect the electricity storage unit and the rectifying circuit to each other.

### E3

The plasma processing apparatus of E1 or E2, further comprising a discharge-only load electrically connected to the electricity storage unit via a switch.

### E4

The plasma processing apparatus of E2 or E3, wherein the rectifying and smoothing unit further comprises a display that is provided so as to be visible from the outside of the ground frame and is configured to display a discharge state of the electricity storage unit.

### E5

The plasma processing apparatus of E4, wherein the rectifying and smoothing unit further comprises:
a voltage detector configured to detect a voltage value of the electricity storage unit; and
a controller configured to control the display to display the discharge state of the electricity storage unit based on the voltage value detected by the voltage detector.

### E6

The plasma processing apparatus of E4 or E5, wherein the display comprises a semiconductor light emitting device.

### E7

The plasma processing apparatus of any one of E1 to E4, wherein the rectifying and smoothing unit further comprises:
a display provided to be visible from the outside of the ground frame;
a voltage detector configured to detect a voltage value of the electricity storage unit; and
a controller configured to control the display to display a charging state of the electricity storage unit based on the voltage value detected by the voltage detector.

### E8

The plasma processing apparatus of E7, wherein the display comprises a semiconductor light emitting device.

### E9

The plasma processing apparatus of any one of E4 to E8, wherein the ground frame comprises:
an optical window that makes the display visible from the outside of the ground frame; and
a metallic shielding member capable of opening and closing the optical window.

### E10

The plasma processing apparatus of any one of E1 to E9, wherein the rectifying and smoothing unit further comprises a smoothing circuit electrically connected between the rectifying circuit and the electricity storage unit.

### E11

A method for controlling a power storage amount, wherein a plasma processing apparatus to which the method for controlling the power storage amount is applied comprises:
a plasma processing chamber;
a substrate support disposed within the plasma processing chamber;
a high frequency power supply configured to generate high frequency power;
an electrode or an antenna electrically connected to the high frequency power supply to receive the high frequency power for generating a plasma from a gas within the plasma processing chamber;
a power consuming member disposed within the plasma processing chamber or the substrate support;
a ground frame that is grounded and surrounds the substrate support together with the plasma processing chamber;
an electricity storage unit disposed within a space surrounded by the ground frame and electrically connected to the power consuming member;
a rectifying and smoothing unit disposed within the space surrounded by the ground frame, including:
   a power feeding input connector comprising a first power feeding input terminal and a second power feeding input terminal and provided so as to be accessible from an outside of the ground frame, and
   a rectifying circuit comprising a diode bridge and connected between the power feeding input connector and the electricity storage unit;
a power feeding output connector comprising a first feeding output terminal and a second power feeding output terminal which are electrically connectable to the first power feeding input terminal and the second power feeding input terminal, the power feeding output connector being detachable from the power feeding input connector; and
a power receiving coil disposed outside the ground frame, electrically connected to the power feeding output connector, and capable of receiving power from a power transmitting coil by electromagnetic induction coupling, and
wherein the method for controlling the power storage amount comprises:
a step of connecting a first power feeding terminal and a second power feeding terminal, which are connected to a DC stabilized power supply disposed outside the ground frame, to the first power feeding input terminal and the second power feeding input terminal; and
a step of feeding power from the DC stabilized power supply to the electricity storage unit.

### E12

The method of E11, wherein the rectifying and smoothing unit further comprises:
a discharge output connector that is accessible from the outside of the ground frame; and
the discharge output connector comprises a first discharge output terminal and a second discharge output terminal that are respectively connected to two power feeding lines that connect the electricity storage unit and the rectifying circuit to each other, and
wherein the method for controlling the power storage amount further comprises:
a step of connecting a first discharge terminal and a second discharge terminal, which are connected to a discharge load disposed outside the ground frame, to the first discharge output terminal and the second discharge output terminal; and
a step of discharging power of the electricity storage unit to the discharge load.

### E13

The method of E11, wherein the plasma processing apparatus further comprises a discharge-only load electrically connected to the electricity storage unit via a switch, and
wherein the method for controlling the power storage amount further comprises:
a step of conducting the electricity storage unit to the discharge-only load via the switch; and
a step of discharging power of the electricity storage unit to the discharge-only load.

### E14

The method of E11, wherein the plasma processing apparatus further comprises a discharge-only load electrically connected to the electricity storage unit via a switch, and
wherein the method for controlling the power storage amount further comprises:
a step of discharging power of the electricity storage unit by supplying the power of the electricity storage unit to the power consuming member;
a step of conducting the electricity storage unit to the discharge-only load via the switch; and
a step of discharging the power of the electricity storage unit to the discharge-only load.

From the foregoing, it will be understood that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A plasma processing apparatus comprising:
a plasma processing chamber;
a substrate support disposed within the plasma processing chamber;
a high frequency power supply configured to generate high frequency power;
an electrode or an antenna electrically connected to the high frequency power supply to receive the high frequency power for generating a plasma from a gas within the plasma processing chamber;
a power consuming member disposed within the plasma processing chamber or the substrate support;
a ground frame that is grounded and surrounds the substrate support together with the plasma processing chamber;
an electricity storage unit disposed within a space surrounded by the ground frame and electrically connected to the power consuming member;
a rectifying and smoothing unit disposed within the space surrounded by the ground frame, including:
a power feeding input connector comprising a first power feeding input terminal and a second power feeding input terminal and provided so as to be accessible from an outside of the ground frame, and
a rectifying circuit comprising a diode bridge and connected between the power feeding input connector and the electricity storage unit;
a power feeding output connector comprising a first feeding output terminal and a second power feeding output terminal which are electrically connectable to the first power feeding input terminal and the second power feeding input terminal, the power feeding output connector being detachable from the power feeding input connector; and
a power receiving coil disposed outside the ground frame, electrically connected to the power feeding output connector, and capable of receiving power from a power transmitting coil by electromagnetic induction coupling.

2. The plasma processing apparatus of claim 1, wherein:
the rectifying and smoothing unit further comprises a discharge output connector that is accessible from the outside of the ground frame; and
the discharge output connector comprises a first discharge output terminal and a second discharge output terminal that are respectively connected to two power feeding lines that connect the electricity storage unit and the rectifying circuit to each other.

3. The plasma processing apparatus of claim 1, further comprising a discharge-only load electrically connected to the electricity storage unit via a switch.

4. The plasma processing apparatus of claim 2, wherein the rectifying and smoothing unit further comprises a display that is provided so as to be visible from the outside of the ground frame and is configured to display a discharge state of the electricity storage unit.

5. The plasma processing apparatus of claim 4, wherein the rectifying and smoothing unit further comprises:
a voltage detector configured to detect a voltage value of the electricity storage unit; and
a controller configured to control the display to display the discharge state of the electricity storage unit based on the voltage value detected by the voltage detector.

6. The plasma processing apparatus of claim 4, wherein the display comprises a semiconductor light emitting device.

7. The plasma processing apparatus of claim 1, wherein the rectifying and smoothing unit further comprises:
a display provided to be visible from the outside of the ground frame;
a voltage detector configured to detect a voltage value of the electricity storage unit; and
a controller configured to control the display to display a charging state of the electricity storage unit based on the voltage value detected by the voltage detector.

8. The plasma processing apparatus of claim 7, wherein the display comprises a semiconductor light emitting device.

9. The plasma processing apparatus of claim 4, wherein the ground frame comprises:
an optical window that makes the display visible from the outside of the ground frame; and
a metallic shielding member capable of opening and closing the optical window.

10. The plasma processing apparatus of claim 1, wherein the rectifying and smoothing unit further comprises a smoothing circuit electrically connected between the rectifying circuit and the electricity storage unit.

11. A method for controlling a power storage amount, wherein a plasma processing apparatus to which the method for controlling the power storage amount is applied comprises:
a plasma processing chamber;
a substrate support disposed within the plasma processing chamber;
a high frequency power supply configured to generate high frequency power;
an electrode or an antenna electrically connected to the high frequency power supply to receive the high frequency power for generating a plasma from a gas within the plasma processing chamber;
a power consuming member disposed within the plasma processing chamber or the substrate support;
a ground frame that is grounded and surrounds the substrate support together with the plasma processing chamber;
an electricity storage unit disposed within a space surrounded by the ground frame and electrically connected to the power consuming member;
a rectifying and smoothing unit disposed within the space surrounded by the ground frame, including:
a power feeding input connector comprising a first power feeding input terminal and a second power feeding input terminal and provided so as to be accessible from an outside of the ground frame, and
a rectifying circuit comprising a diode bridge and connected between the power feeding input connector and the electricity storage unit;
a power feeding output connector comprising a first feeding output terminal and a second power feeding output terminal which are electrically connectable to the first power feeding input terminal and the second power feeding input terminal, the power feeding output connector being detachable from the power feeding input connector; and
a power receiving coil disposed outside the ground frame, electrically connected to the power feeding output connector, and capable of receiving power from a power transmitting coil by electromagnetic induction coupling, and
wherein the method for controlling the power storage amount comprises:
a step of connecting a first power feeding terminal and a second power feeding terminal, which are connected to a DC stabilized power supply disposed outside the ground frame, to the first power feeding input terminal and the second power feeding input terminal; and
a step of feeding power from the DC stabilized power supply to the electricity storage unit.

12. The method of claim 11, wherein the rectifying and smoothing unit further comprises:
a discharge output connector that is accessible from the outside of the ground frame; and
the discharge output connector comprises a first discharge output terminal and a second discharge output terminal that are respectively connected to two power feeding lines that connect the electricity storage unit and the rectifying circuit to each other, and
wherein the method for controlling the power storage amount further comprises:
a step of connecting a first discharge terminal and a second discharge terminal, which are connected to a discharge load disposed outside the ground frame, to the first discharge output terminal and the second discharge output terminal; and
a step of discharging power of the electricity storage unit to the discharge load.

13. The method of claim 11, wherein the plasma processing apparatus further comprises a discharge-only load electrically connected to the electricity storage unit via a switch, and
wherein the method for controlling the power storage amount further comprises:
a step of conducting the electricity storage unit to the discharge-only load via the switch; and
a step of discharging power of the electricity storage unit to the discharge-only load.

14. The method of claim 11, wherein the plasma processing apparatus further comprises a discharge-only load electrically connected to the electricity storage unit via a switch, and
wherein the method for controlling the power storage amount further comprises:
a step of discharging power of the electricity storage unit by supplying the power of the electricity storage unit to the power consuming member;
a step of conducting the electricity storage unit to the discharge-only load via the switch; and
a step of discharging the power of the electricity storage unit to the discharge-only load.
